(19) United States
(12) Patent Application Publication
(10) Pub. No.: US 2018/0197451 A1
(43) Pub. Date: Jul. 12, 2018

(54) Light System

(71) Applicant: Enlighten Enterprises Inc., Chicago, IL (US)

(72) Inventor: Jacques Laramie, Chicago, IL (US)

(73) Assignee: Enlighten Enterprises Inc., Chicago, IL (US)

(21) Appl. No.: 15/742,411

(22) PCT Filed: Jul. 6, 2016
(86) PCT No.: PCT/US16/41210

§ 371 Date: Jan. 5, 2018

Related U.S. Application Data
(60) Provisional application No. 62/189,202, filed on Jul. 6, 2015.
(60) Provisional application No. 62/233,026, filed on Sep. 25, 2015.

(51) Int. Cl. G09G 3/20; G02F 1/17; G02F 1/1334; G02F 1/133; H01L 27/32

(52) U.S. Cl. CPC G09G 3/2003; G02F 1/172; G02F 1/1334; G02F 2001/13324; H01L 27/3211; H01L 27/3232; G02F 1/13306

(57) ABSTRACT

A system, including: a power source, a multi-layer device, and an electronic controller. The multi-layer device is connected to the power source and has two sides: a viewing side and a second side opposite the viewing side. The multi-layer device permits or prevents light to pass therethrough from the second side toward the viewing side. The multi-layer device includes: a coloring layer group having a plurality of pixels, each pixel having at least three sub-pixels corresponding to different colors; and a shutter layer group having a unique subpixel shutter corresponding to each sub-pixel of the coloring layer group. The electronic controller is connected to the power source and the multi-layer device, and is adapted to control each sub-pixel shutter to selectively permit or prevent passage of an amount of light therethrough; and control each combination of sub-pixel shutter and corresponding coloring layer sub-pixel to produce pixels on the viewing side that can be any of opaque black.

### CROSS-REFERENCE TO RELATED APPLICATION

This application claims priority under 35 USC § 119(e) from U.S. Provisional Patent Application Ser. Nos. 62/189,202 and 62/233,026, respectively filed on Jul. 6, 2015 and Sep. 25, 2015, the disclosures of which are incorporated herein by reference in their entirety.

### FIELD OF THE INVENTION

The present invention relates to a light system, and more particularly, to a light system that selectively permits and prevents the passage of light therethrough.

### BACKGROUND OF THE INVENTION

Blinds and window coverings help control how much of the sun's light and heat enter people's homes, while providing privacy and decor. Traditional solutions have many moving parts, are fragile, and only block some of the light, some of the time. Automated solutions can be bulky, slow, loud, and expensive, and still are not entirely effective. Installing newer, transparent LCD smart windows requires replacement of the entire window, and such LCD smart windows have limited color capability. Better solutions for covering windows or selectively permitting and preventing passage of light through a device in other locations are desirable.

### SUMMARY OF EMBODIMENTS OF THE INVENTION

The aspects of the present invention are achieved by providing a system, including: a power source, a multi-layer device, and an electronic controller. The multi-layer device is connected to the power source and has two sides: a viewing side and a second side opposite the viewing side. The multi-layer device permits or prevents light to pass therethrough from the second side toward the viewing side. The multi-layer device includes: a coloring layer group having a plurality of pixels, each pixel having at least three sub-pixels corresponding to different colors; and a shutter layer group having a unique sub-pixel shutter corresponding to each sub-pixel of the coloring layer group. The electronic controller is connected to the power source and the multi-layer device, and is adapted to control each sub-pixel shutter to selectively permit or prevent passage of an amount of light therethrough; and control each combination of sub-pixel shutter and corresponding coloring layer sub-pixel to produce pixels on the viewing side that can be any of opaque black, at least substantially opaque white, at least substantially opaque color, transparent, transparent white, and transparent color.

Additional and/or other aspects and advantages of the present invention will be set forth in the description that follows, or will be apparent from the description, or may be learned by practice of the invention.

### BRIEF DESCRIPTION OF THE DRAWINGS

The above and/or other aspects and advantages of embodiments of the invention will be more readily appreciated from the following detailed description, taken in conjunction with the accompanying drawings, in which:

FIGS. 1 and 2 are legends for identifying cross hatchings used in this application to consistently illustrate colors and elements using black and white drawings;

FIG. 3 is a diagram illustrating an additive coloring system;

FIG. 4 is a diagram illustrating three sub-pixels on a screen;

FIG. 5 is a diagram illustrating a pixel mixing the sub pixels of FIG. 4 on a retina;

FIG. 6 is a diagram illustrating the perception of white from the pixel of FIG. 5;

FIG. 7 is an exploded, cross-sectional diagram of a liquid crystal display (LCD) assembly on a sub-pixel level;

FIG. 8 is a diagram of an LCD assembly producing an opaque white pixel;

FIG. 9 is a diagram of an LCD assembly producing an opaque color pixel;

FIG. 10 is a diagram of an LCD assembly producing an opaque black pixel;

FIG. 11 is a diagram of an LCD assembly displaying an exemplary image;

FIG. 12 is an exploded, cross-sectional diagram of a see-through LCD assembly on a sub-pixel level;

FIG. 13 is a diagram of a see-through LCD assembly producing a transparent white pixel;

FIG. 14 is a diagram of a see-through LCD assembly producing a transparent color pixel;

FIG. 15 is a diagram of a see-through LCD assembly producing an opaque black pixel;

FIG. 16 is a diagram of a see-through LCD assembly displaying the exemplary image;

FIG. 17 is an exploded, cross-sectional diagram of an organic light emitting diode (OLED) assembly on a sub-pixel level;

FIG. 18 is a diagram of an OLED assembly producing an opaque white pixel;

FIG. 19 is a diagram of an OLED assembly producing an opaque color pixel;

FIG. 20 is a diagram of an OLED assembly producing an opaque black pixel;

FIG. 21 is a diagram of an OLED assembly displaying the exemplary image;

FIG. 22 is an exploded, cross-sectional diagram of a see-through OLED assembly on a sub-pixel level;

FIG. 23 is a diagram of a see-through OLED assembly producing a transparent white pixel;

FIG. 24 is a diagram of a see-through OLED assembly producing a transparent color pixel;

FIG. 25 is a diagram of a see-through OLED assembly producing a black, half-silvered pixel;

FIG. 26 is a diagram of a see-through OLED assembly displaying the exemplary image;

FIG. 27 is a block diagram of a system in accordance with an embodiment of the present invention;

FIG. 28 is an exploded, cross-sectional diagram of a system on a sub-pixel level in accordance with another embodiment of the present invention;

FIG. 29 is a diagram of the system of FIG. 28 producing a transparent white pixel;

FIG. 30 is a diagram of the system of FIG. 28 producing a transparent color pixel;

FIG. 31 is a diagram of the system of FIG. 28 producing an opaque black pixel;

FIG. 32 is a diagram of the system of FIG. 28 producing a substantially opaque white pixel;

FIG. 33 is a diagram of the system of FIG. 28 producing a substantially opaque color pixel;

FIG. 34 is another diagram of the system of FIG. 28 producing an opaque black pixel;

FIG. 35 is a diagram of the system of FIG. 28 displaying the exemplary image;

FIG. 36 is an exploded, cross-sectional diagram of a system on a sub-pixel level in accordance with another embodiment of the present invention;

FIG. 37 is a diagram of the system of FIG. 36 producing a substantially opaque white pixel;

FIG. 38 is a diagram of the system of FIG. 36 producing a substantially opaque color pixel;

FIG. 39 is a diagram of the system of FIG. 36 producing an opaque black pixel;

FIG. 40 is a diagram of the system of FIG. 36 producing a transparent pixel;

FIG. 41 is a diagram of the system of FIG. 36 producing a transparent color pixel;

FIG. 42 is a diagram of the system of FIG. 36 displaying the exemplary image;

FIG. 43 is an exploded, cross-sectional diagram of a system on a sub-pixel level in accordance with another embodiment of the present invention;

FIG. 44 is a diagram of the system of FIG. 43 producing a transparent pixel;

FIG. 45 is a diagram of the system of FIG. 43 producing a transparent color pixel;

FIG. 46 is a diagram of the system of FIG. 43 producing a transparent white pixel;

FIG. 47 is a diagram of the system of FIG. 43 producing an opaque white pixel;

FIG. 48 is a diagram of the system of FIG. 43 producing an opaque color pixel;

FIG. 49 is a diagram of the system of FIG. 43 producing an opaque black pixel;

FIG. 50 is a diagram of the system of FIG. 43 displaying the exemplary image;

FIG. 51 is an exploded, cross-sectional diagram of a system on a sub-pixel level in accordance with another embodiment of the present invention;

FIG. 52 is a diagram of the system of FIG. 51 producing a transparent pixel;

FIG. 53 is a diagram of the system of FIG. 51 producing a transparent color pixel;

FIG. 54 is a diagram of the system of FIG. 51 producing a transparent color pixel;

FIG. 55 is a diagram of the system of FIG. 51 producing a substantially opaque white pixel;

FIG. 56 is a diagram of the system of FIG. 51 producing an opaque color pixel;

FIG. 57 is a diagram of the system of FIG. 51 producing an opaque black pixel;

FIG. 58 is a diagram of the system of FIG. 51 producing a transparent white pixel;

FIG. 58 is a diagram of the system of FIG. 51 producing a substantially opaque white pixel;

FIG. 60 is a diagram of the system of FIG. 51 producing an opaque white pixel

FIG. 61 is a diagram of the system of FIG. 51 displaying the exemplary image; and

FIGS. 62-67 illustrate other embodiments of the present invention.

### DETAILED DESCRIPTION OF EMBODIMENTS OF THE PRESENT INVENTION

Reference will now be made in detail to embodiments of the present invention, which are illustrated in the accompanying drawings, wherein like reference numerals refer to like elements throughout. The embodiments described herein exemplify, but do not limit, the present invention by referring to the drawings.

It will be understood by one skilled in the art that this disclosure is not limited in its application to the details of construction and the arrangement of components set forth in the following description or illustrated in the drawings. The embodiments herein are capable of other embodiments, and capable of being practiced or carried out in various ways. Also, it will be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical or mechanical connections or couplings. Further, terms such as up, down, bottom, and top are relative, and are employed to aid illustration, but are not limiting.

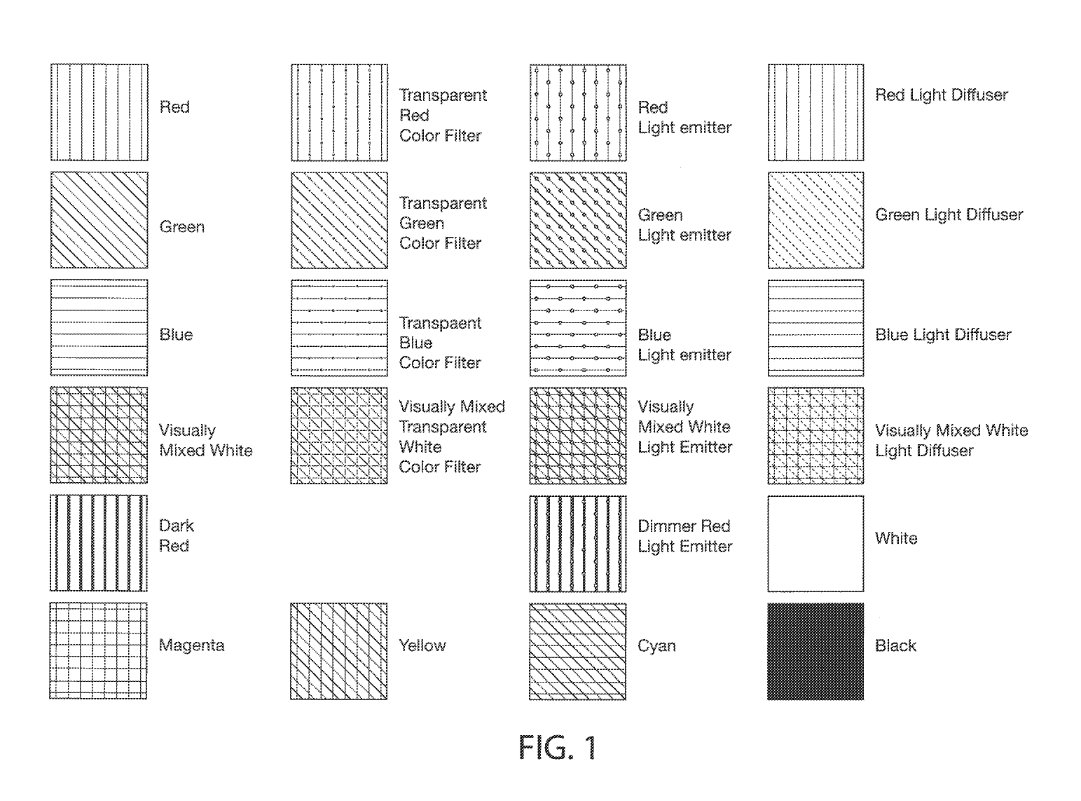

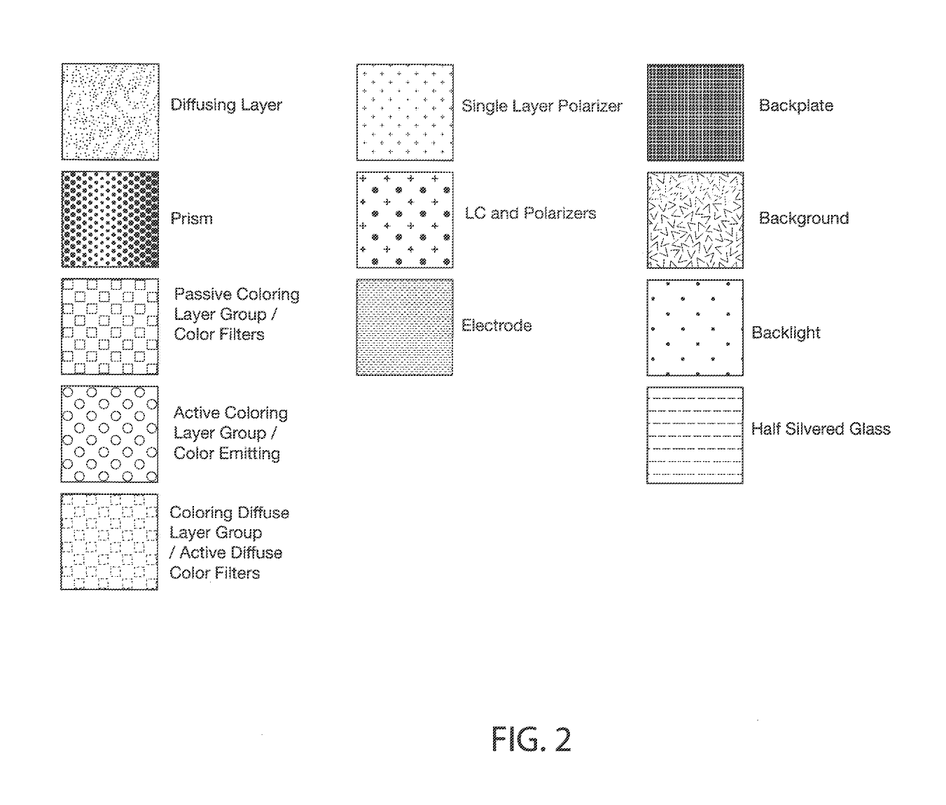

FIGS. 1 and 2 are keys or legends for identifying cross hatchings used in this application to consistently illustrate colors and elements using black and white drawings.

Regarding the creation of color, the most familiar method is subtractive coloring, in which colors are created by subtracting (absorbing) parts of the spectrum of light present in ordinary white light. This is accomplished, for example, by colored pigments or dyes, such as those in paints, inks, and the three dye layers in typical color photographs on film.

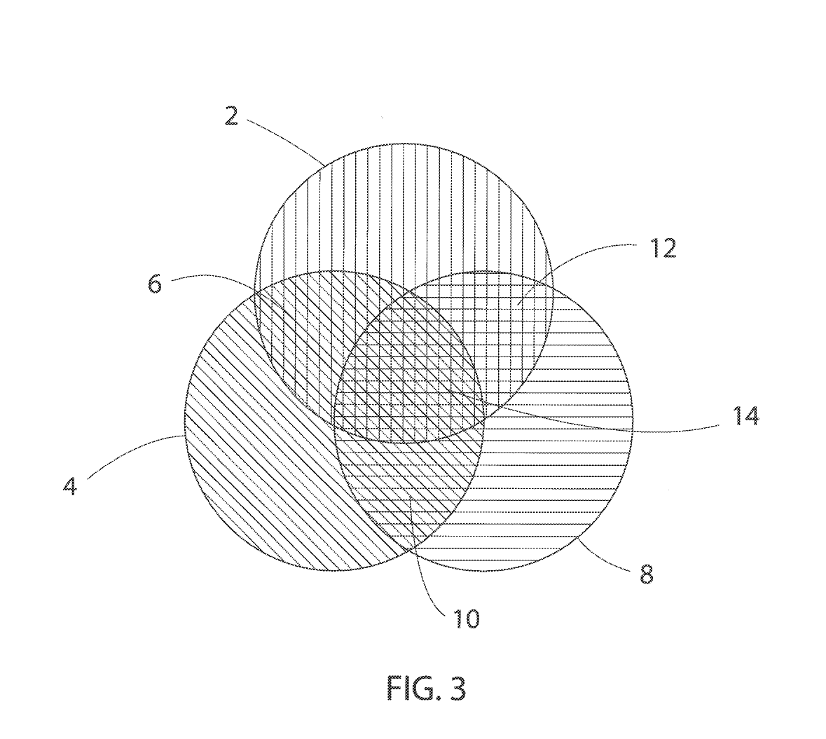

In contrast, additive color is color created by mixing a number of different light colors, with shades of red, green, and blue being the most common primary colors used in an additive color system. The combination of two of these standard three additive primary colors in equal proportions produces an additive secondary color, i.e., cyan, magenta or yellow. More specifically, as shown in FIG. 3, if an area of red light 2 and an area of green light 4 are partially overlaid, the overlapping area produces an area of yellow light 6. Similarly, if an area of green light 4 and an area of blue light 8 are partially overlaid, the overlapping area produces an area of cyan light 10, and if an area of blue light 8 and an area of red light 2 are overlaid, the overlapping area produces an area of magenta light 12.

Further, when the areas of red light 2, green light 4, and blue light 8 are overlaid, the overlapping area produces an area of white light 14

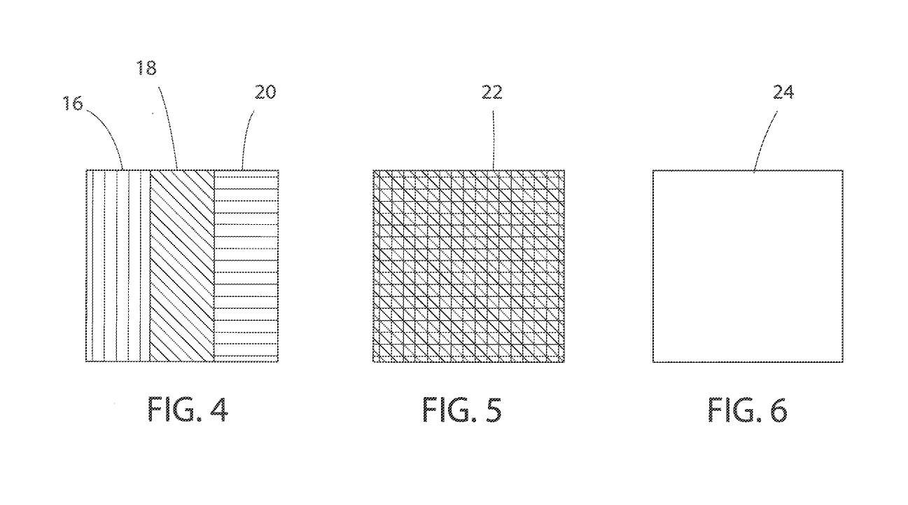

One example of additive color can be found in the overlapping projected colored lights often used in theatrical lighting for plays, concerts, circus shows and night clubs. Computer monitors and televisions are probably the most common examples of additive coloring. If viewed with a sufficiently powerful magnifying lens, each pixel in cathode ray tube (CRT), liquid crystal display (LCD), and most other types of color video displays is composed of red, green, and blue sub-pixels 16, 18, 20 (see FIG. 4), the light from which combines in various proportions to produce all the other colors as well as white and shades of gray. The colored sub-pixels do not overlap on the screen, but when viewed from a normal distance they overlap and blend on the eye's retina, as shown in FIG. 5, and yield the same result as external superimposition. In this case (FIG. 6), the pixel 22 seen on a human retina in FIG. 5, that is a result of the red, green, and blue sub-pixels of FIG. 4, is perceived as a white pixel 24 in the human brain.

When mixing additive colors, results are often counterintuitive for those accustomed to the subtractive color system (e.g., pigments, dyes, inks, and other substances that present color to the eye by reflection rather than emission). For example, in subtractive color systems, green is a combination of yellow and cyan. As previously noted with respect to FIG. 3, in additive coloring, the combination of red and green yields yellow. Additive color is a result of the way the eye detects color, and is not a property of light itself. There is a significant difference between a pure spectral yellow light, with a wavelength of approximately 580 nm, and a mixture of red and green light. But both stimulate the human eye in a similar manner, so that the difference is not detected, and both are perceived as yellow light.

On the market today, there are generally two categories of screens available: opaque and see-through. Opaque screens are what most people have as TVs in their homes or use day to day as computer monitors or cellphones. Often they use backlights to create vivid images. See-through screens are less common, though can be found in store displays. Due to their see-through nature, a viewer can see through the colored image being rendered on the see-through screen to objects and lights in the background.

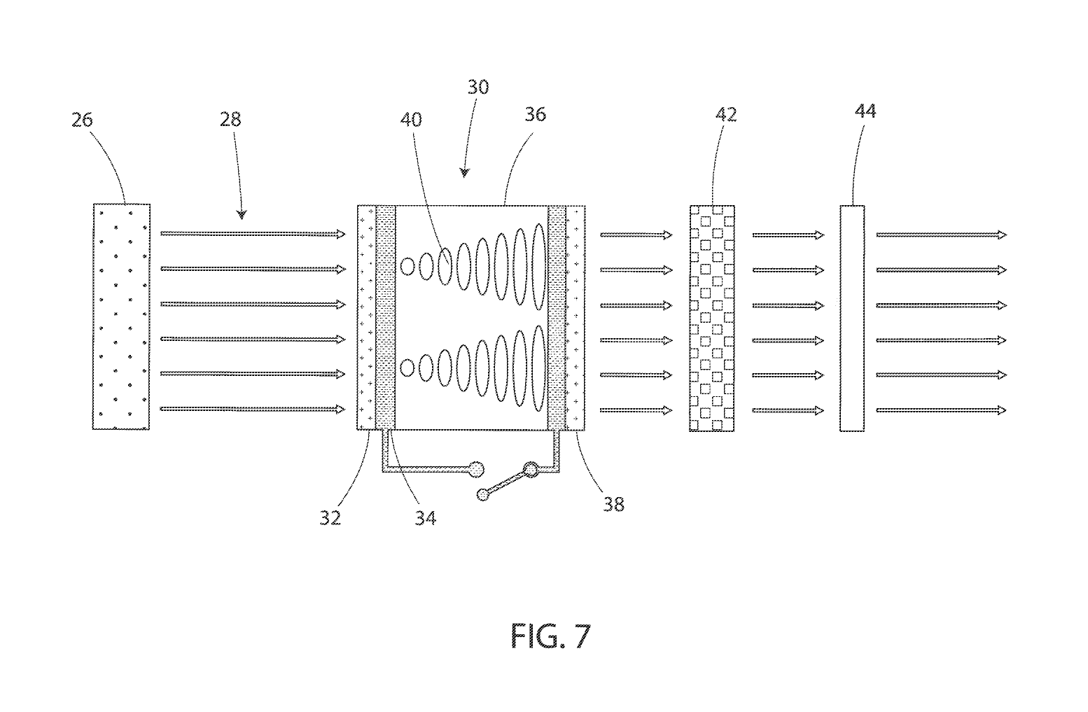

One example of an opaque screen is a liquid crystal display (LCD) or LCD assembly. The design, construction and operation of LCDs is well known to those of ordinary skill in the art. See, e.g., “Liquid-crystal display”, https://en.wikipedia.org/wiki/Liquid-crystal display (retrieved on Jul. 6, 2016) and references cited therein, all incorporated herein by reference. An LCD creates an even, white light with its optics system and controls the particular amount of that light (or luminance) that passive color filters using sub-pixel “shutter-like” mechanisms. These sub-pixel shutters control the luminance values of colored sub-pixels, which in combination create a single color value per pixel. FIG. 7 is an exploded diagram of a LCD assembly on a sub-pixel level In more detail, as shown in FIG. 7, a backlight 26 produces an even, white light 28, which enters a polarizing filter 30 to filter the light 28.

An example of the polarizing filter 30 includes a first polarizing layer 32, an electrode 34 that drives a liquid crystal layer 36, and a second polarizing layer 38 that is oriented to be orthogonal to the first polarizing layer 32. In operation, when the liquid layer is un-powered (as shown in FIG. 7), the liquid crystals 40 form a helix and turn the light 28 ninety degrees. This turning aligns the light with the second polarizing layer 38, and the light 28 is permitted to pass therethrough to a sub-pixel passive color filter 42, which colorizes the light 28. The colorized light 28 then passes through a viewing side substrate 44. Typically, the sub-pixel passive color filter would be red, green, or blue, and a group of three (red, green, and blue) would together blend to form a pixel.

If the electrode 34 powers the liquid crystal layer 36, the liquid crystals align linearly and no longer turn the light. The un-turned light cannot pass through the second polarizing layer 38, and as a result, the sub-pixel is would show up as opaque black through viewing side substrate 44.

Put another way, the LCD transforms a single light source (26) into what appears to be an even white rectangular glowing white surface. The optic system does two things for the LCD, it provides a source of light and it provides white values. But it does not render any image; it merely illuminates it. As an analogy, the LCD optic system can be thought of as a white piece of paper onto which an image is created. In this way, the colors are pure.

Using sub-pixel size shutters, which are made of electronically controlled liquid crystals (LCs) sandwiched between two polarized films with orientations 90 degrees to one another, a precise amount of light can be permitted to pass through. The amount of light is proportional to the amount of energy applied to the LC. Sub-pixel color filters, which are typically red, green and blue, are transparent and are each illuminated by the light passing through the final polarizer. Their combined values together create a single color value per pixel

The LCD has a lot of control over luminance and white values, as the backlight is a very precise white color and very precise brightness. But there is no control over opacity. The LCD is always opaque. The light from the sun cannot make it through the back of the display.

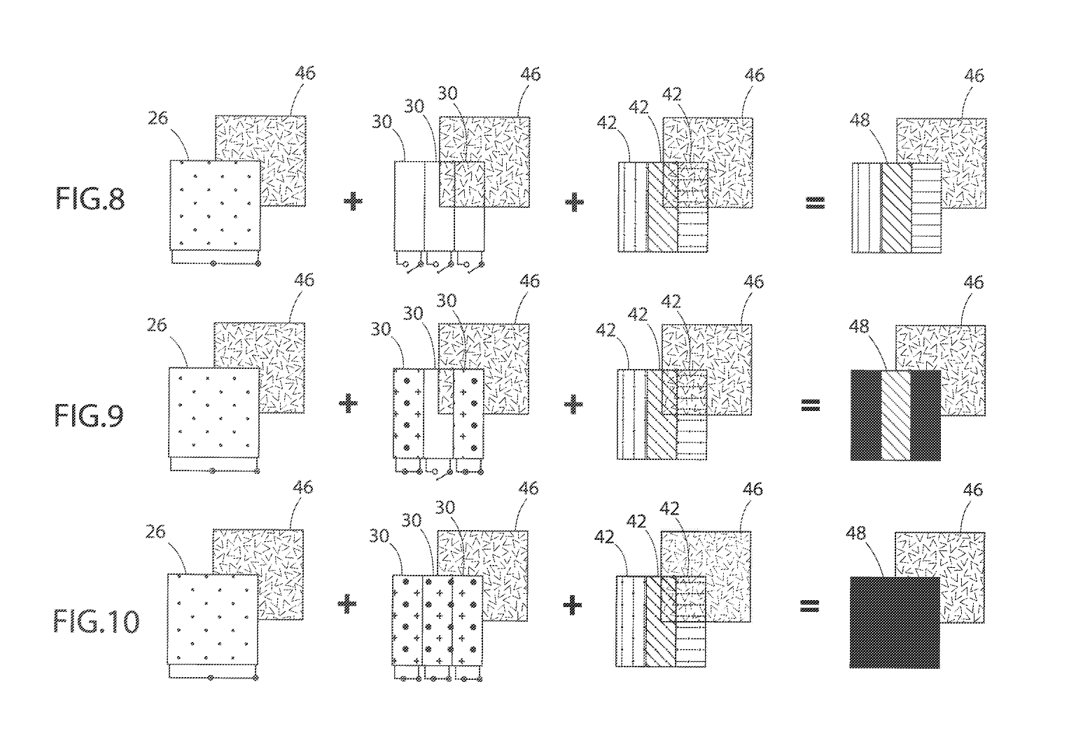

FIG. 8 is a diagram of an LCD producing an opaque white pixel. In FIG. 8, the backlight 26 is illustrated as being in front of a background 46, and shows that the backlight 26 (and thus, the LCD) is opaque. In this state, a group of three sub-pixel polarizing filters 30 are un-powered, so the light passes therethrough to a group of red, green, and blue passive filters 42, which together form a red, green, and blue pixel 48, which mixes in a human eye to be perceived as an opaque white pixel 48. The background 46 is shown behind the sub-pixel polarizing filters and the sub-pixel passive filters 42 for exemplary purposes to illustrate whether or not these elements are opaque in a particular state.

FIG. 9 is a diagram of an LCD producing an opaque color pixel. In this state, the sub-pixel polarizing filters 30 corresponding to the red and blue passive sub-pixel filters 42 are powered, and thus, are blocking the light from passing therethrough. But the sub-pixel polarizing filter 30 corresponding to the green passive sub-pixel filter 42 is un-powered, and therefore allows the light to reach and pass through the green passive sub-pixel filter 42 to form an opaque green pixel 48.

FIG. 10 is a diagram of an LCD producing an opaque black pixel. In this state, all three sub-pixel polarizing filters 30 are powered, and thus block the light, thereby producing an opaque black pixel 48.

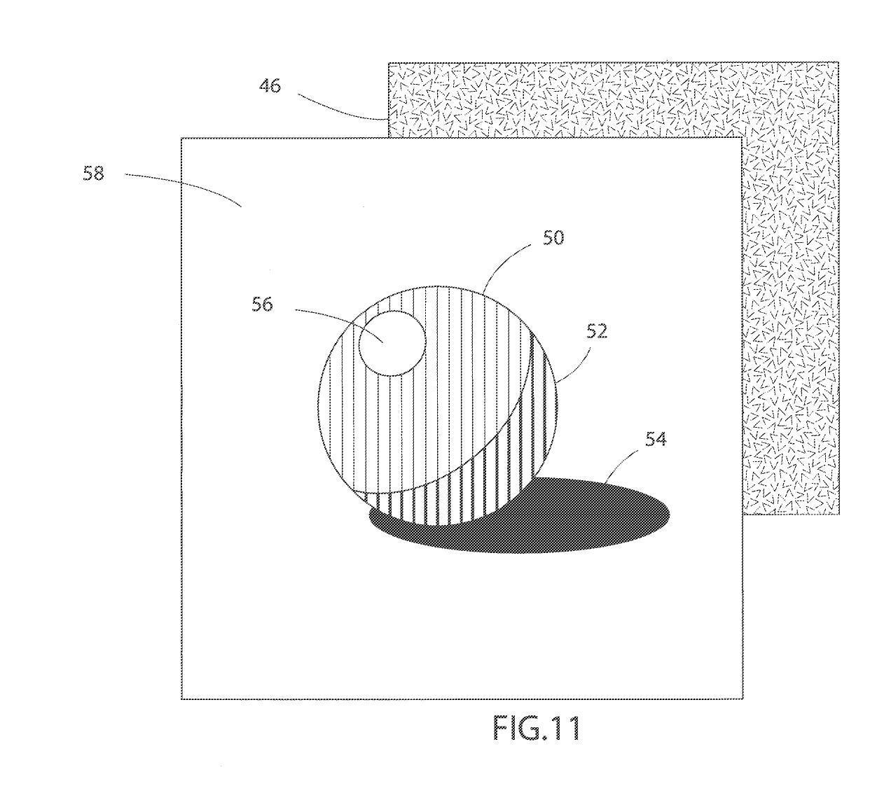

FIG. 11 is a diagram of an LCD displaying an exemplary image. This exemplary image shows image pixels that form a red ball with a lighter red upper portion 50, a darker red lower portion 52, a shadow area 54, and a white highlight area 56 that represents a reflection of the light that casts the shadow 54. The exemplary image also shows the non-image pixel area 58. The exemplary image will be subsequently employed to compare and contrast images produced by different image producing systems, and is shown in front of the background 46.

For the LCD, all pixels are opaque Thus, the non-image pixel area 58 and the white highlight area 56 are opaque white, the lighter and darker red areas 50 and 52 are opaque red, and the shadow area 54 is opaque black.

In a see-through LCD or LCD assembly, there is no even, white backlight; instead, it uses natural or ambient light. As a result, when the sub-pixel shutters are open to allow light to reach the color filters, the colors can be distorted by what is directly behind them, because the source of light is not a pure white backlight. For example, if a see-through is placed on a window that looks out at a pine tree, for the image pixels that are aligned with the pine tree from a viewer's perspective, those image pixels will be receiving light reflected from the pine tree, thereby distorting the color of those image pixels.

See-through LCDs have less control over luminance because they rely on their environments for a light source. Further, they only have partial control over opacity. Darker colors are more opaque than lighter colors, and white is completely transparent or clear. This is because polarizers block light, while color filters simple colorize the light that is coming through. Thus, one would be able to see through the display more easily when it is displaying lighter colors than when the colors are dark.

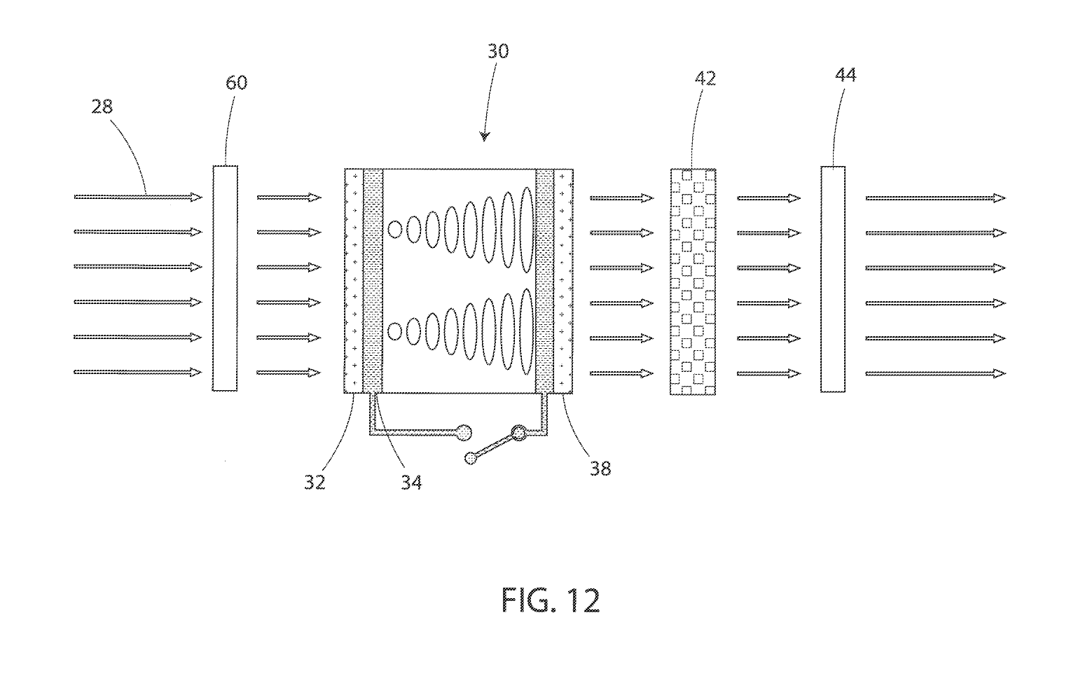

FIG. 12 is an exploded, cross-sectional diagram of a see-through LCD assembly on a sub-pixel level. The see-through LCD assembly receives natural or ambient light 28 through a light receiving side substrate or rear substrate 60. The light then enters the sub-pixel polarizing filter 30, which functions in the same manner as the sub-pixel polarizing filter 30 of FIG. 7. In other words, when the sub-pixel polarizing filter 30 is un-powered, the light 28 passes through, and when it is powered, the light 28 does not pass through. Light 28 that does pass through the sub-pixel polarizing filter 30 passes through the passive sub-pixel filter 42 and through the viewing side substrate 44.

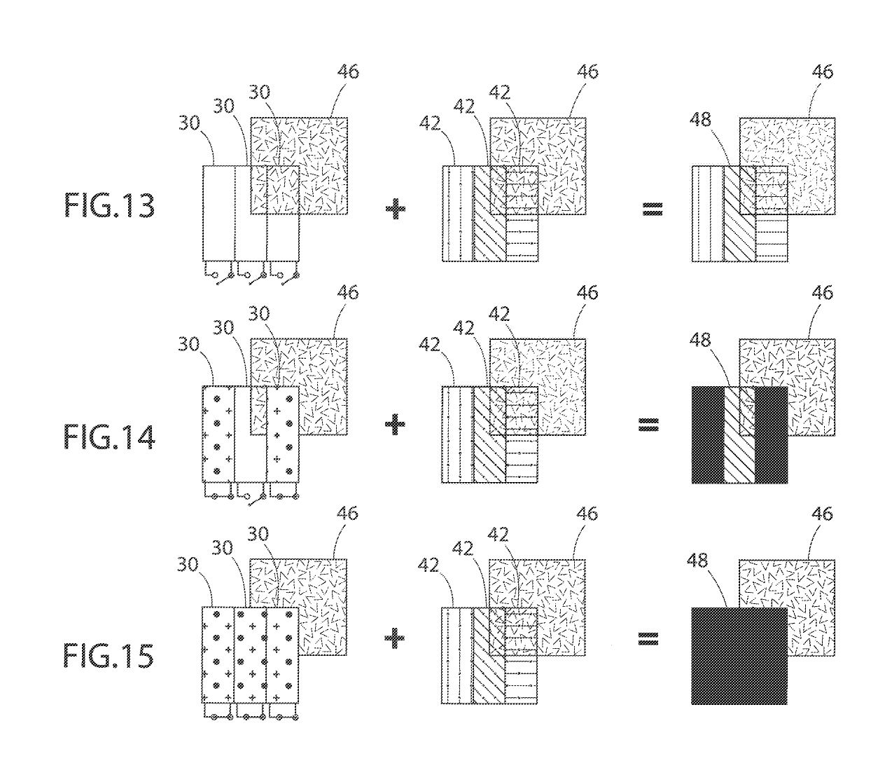

FIG. 13 is a diagram of a see-through LCD producing a transparent white pixel (which in the attempt with a see through LCD results as completely transparent or clear). In this state, a group of three sub-pixel polarizing filters 30 are un-powered, so the received light passes therethrough to a group of red, green, and blue passive filters 42, which together form a red, green, and blue pixel 48, which mixes in a human eye to be perceived as a completely transparent pixel 48.

FIG. 14 is a diagram of a see-through LCD producing a transparent color pixel. In this state, the sub-pixel polarizing filters 30 corresponding to the red and blue passive sub-pixel filters 42 are powered, and thus, are blocking the received light from passing therethrough. But the sub-pixel polarizing filter 30 corresponding to the green passive sub-pixel filter 42 is un-powered, and therefore allows the received light to reach and pass through the green passive sub-pixel filter 42 to form a transparent green pixel 48.

FIG. 15 is a diagram of a see-through LCD producing an opaque black pixel. In this state, all three sub-pixel polarizing filters 30 are powered, and thus block the light, thereby producing an opaque black pixel 48.

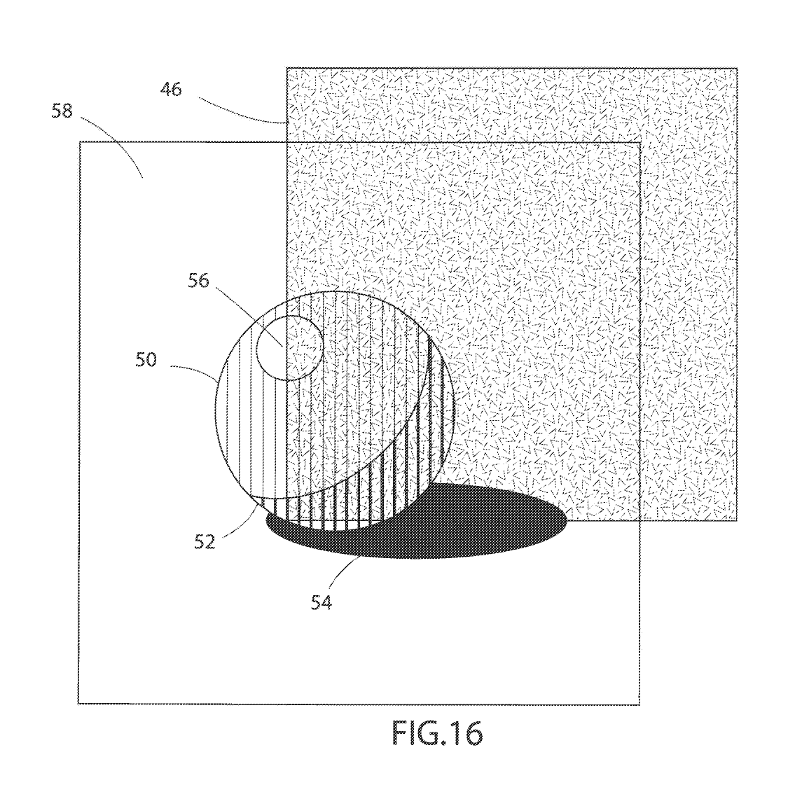

FIG. 16 is a diagram of a see-through LCD displaying the exemplary image. For the see-through LCD, all pixels are transparent except black pixels. Thus, the non-image pixel area 58 and the white highlight area 56 are transparent white (which is completely transparent or clear), the lighter and darker red areas 50 and 52 are transparent red, and the shadow area 54 is opaque black.

In an organic light emitting diode (OLED) or OLED assembly, the colored sub-pixels themselves illuminate and do not rely on a backlight for illumination. Additionally, the colored sub-pixels have no need for sub-pixel shutters to achieve darker colors or black; the intensity of the colored sub-pixels are merely turned down or completely off by an electronic controller. This reduction in layers makes OLED assemblies thinner in depth than typical LCD assemblies. The OLED assembly produces an image by modulating the luminance values of the red, green, and blue (RGB) sub-pixels per pixel. Generally, the OLED sits directly in front of a black background or backplate. Like an LCD assembly, the OLED assembly is completely opaque and a viewer in front cannot see through the backplate. The design, construction and operation of OLED assemblies is well known to those of ordinary skill in the art. See, e.g., “OLED”, https://en.wikipedia.org/wiki/OLED (retrieved on Jul. 6, 2016) and references cited therein, all incorporated herein by reference.

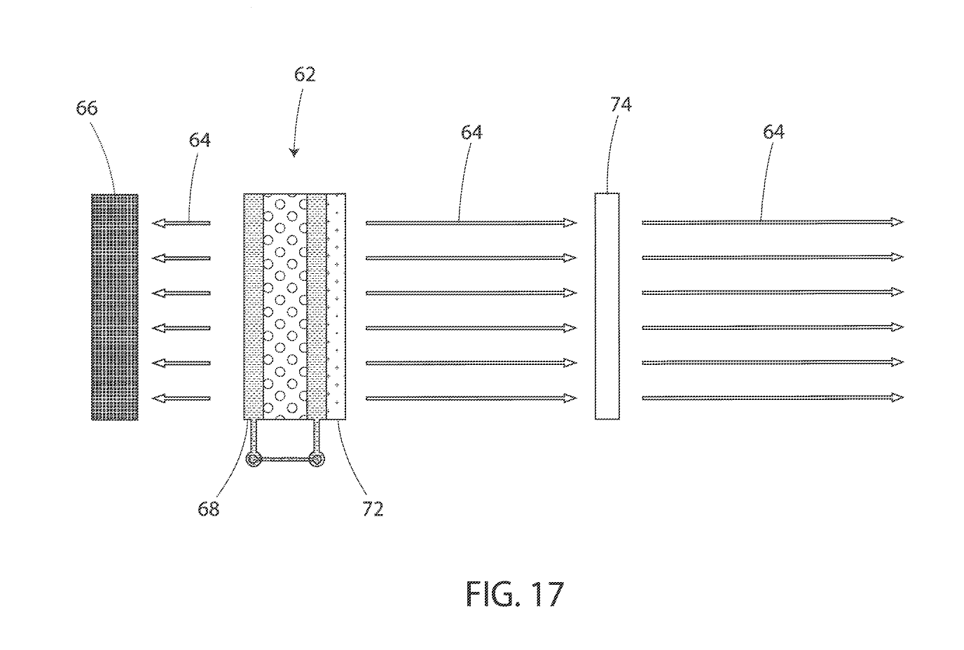

FIG. 17 is an exploded, cross-sectional diagram of an organic light emitting diode (OLED) assembly on a sub-pixel level. As shown in FIG. 17, a light emitting portion 62 emits light 64 both toward and away from the viewer. The light 64 emitted away from the viewer is absorbed by a black backplate 66. The light emitting portion 62 includes an electrode driving an active coloring emitter 70, and a single layer polarizer 72. Light 64 emitted from the active coloring emitter 70 toward the viewer passes through the single layer polarizer 72 and then through the viewing side substrate 74 toward the viewer.

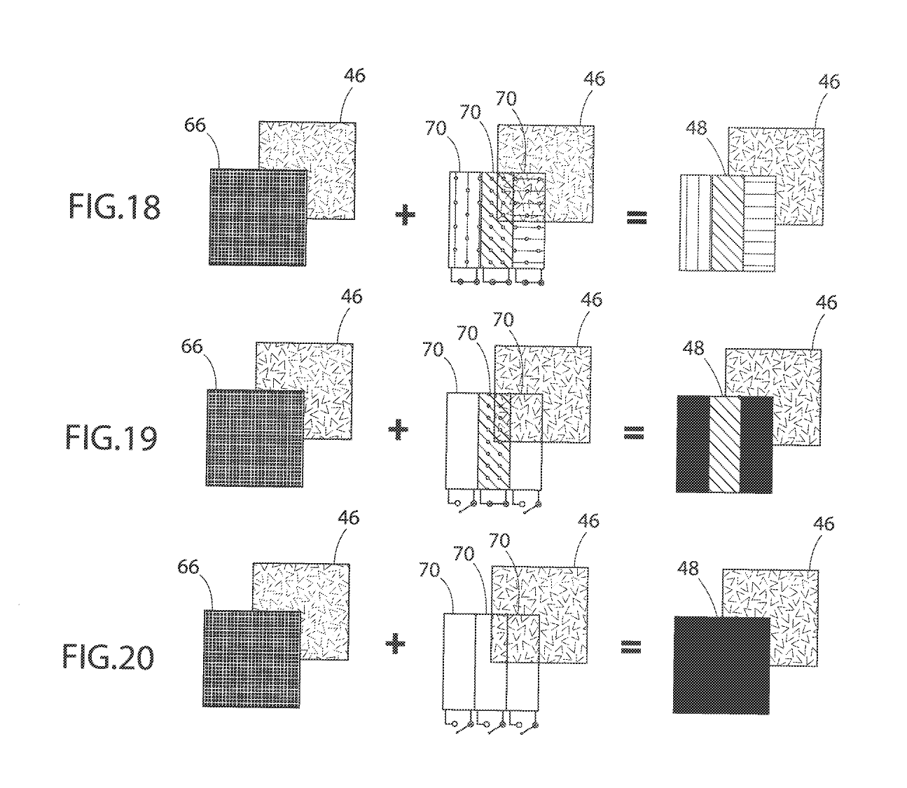

FIG. 18 is a diagram of an OLED assembly producing an opaque white pixel. In FIG. 18, the backplate 66 is illustrated as being in front of the background 46, and shows that the backplate 66 (and thus, the OLED assembly) is opaque. In this state, a group of three sub-pixel active color emitters 70 are driven by the electrode 68 to respectively emit red, green, and blue sub-pixel light, which passes through the single layer polarizer 72 to create an opaque white pixel 48.

FIG. 19 is a diagram of an OLED assembly producing an opaque color pixel. In this state, the red and blue sub-pixel active emitters 70 are not driven by the electrode 68, and therefore do not respectively produce red and blue light. The electrode 68, however, drives the green sub-pixel active emitter 70 to produce green light which passes through the single layer polarizer 72 to create an opaque green pixel 48.

FIG. 20 is a diagram of an OLED assembly producing an opaque black pixel. In this state, none of the active coloring emitters 70 are driven by the electrode 68, and therefore, do not produce light, which results in an opaque pixel 48.

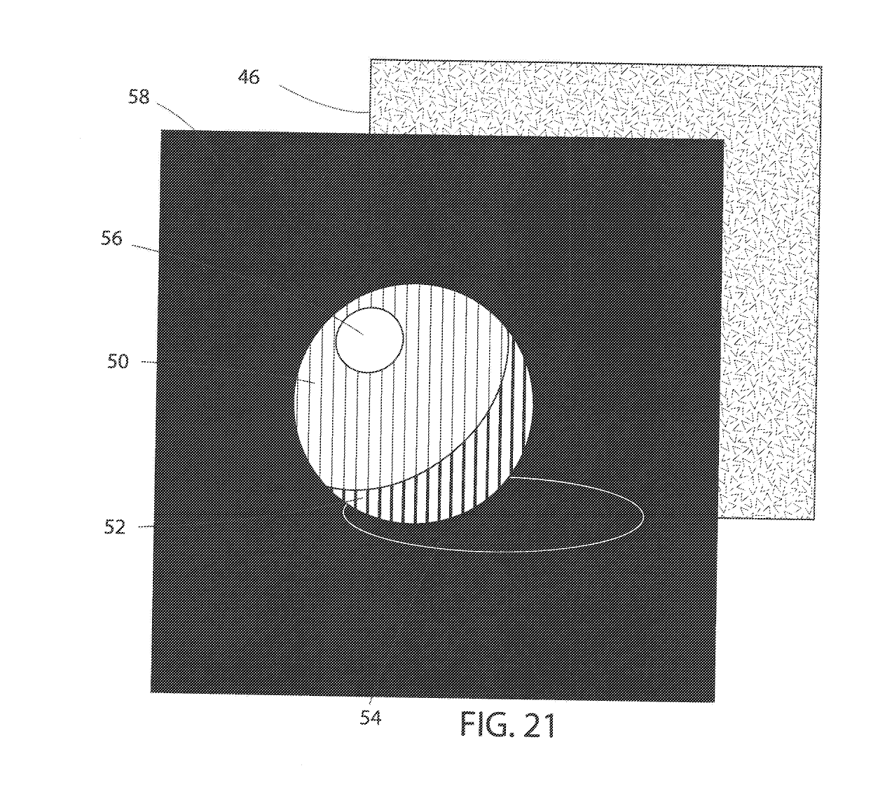

FIG. 21 is a diagram of an OLED assembly displaying the exemplary image. As with the LCD assembly, black white, and color are opaque. In contrast to the LCD assembly, however, the non-image pixels are opaque black. For the OLED assembly, all pixels are opaque. Thus, the non-image pixel area 58 is opaque black, the white highlight area 56 is opaque white, the lighter and darker red areas 50 and 52 are opaque red, and the shadow area 54 is opaque black.

In a see-through OLED, the colors themselves illuminate and do not rely on a backlight for illumination. The OLED produces an image by modulating the luminance values of the RGB subpixels per pixel. The see-through OLED uses a half-silvered or half-mirrored layer to partially control opacity. The half-silvered layer does not render an image. But the see-through OLED assembly is subject to unwanted transparency if what is on the other side is brighter than the illuminated pixels themselves. A see-through OLED assembly does not block light at all.

In a see-through OLED, all colors emit light and are some percentage transparent by their nature. The transparency becomes more noticeable when there is a light source of similar or greater intensity than the OLEDs themselves, on the other side of the half-silvered substrate. In other words, see-through OLED technology has more control over luminance, but less control over opacity. The typical see-through OLED actually gets clearer as the color values and luminances (per pixel) approach black.

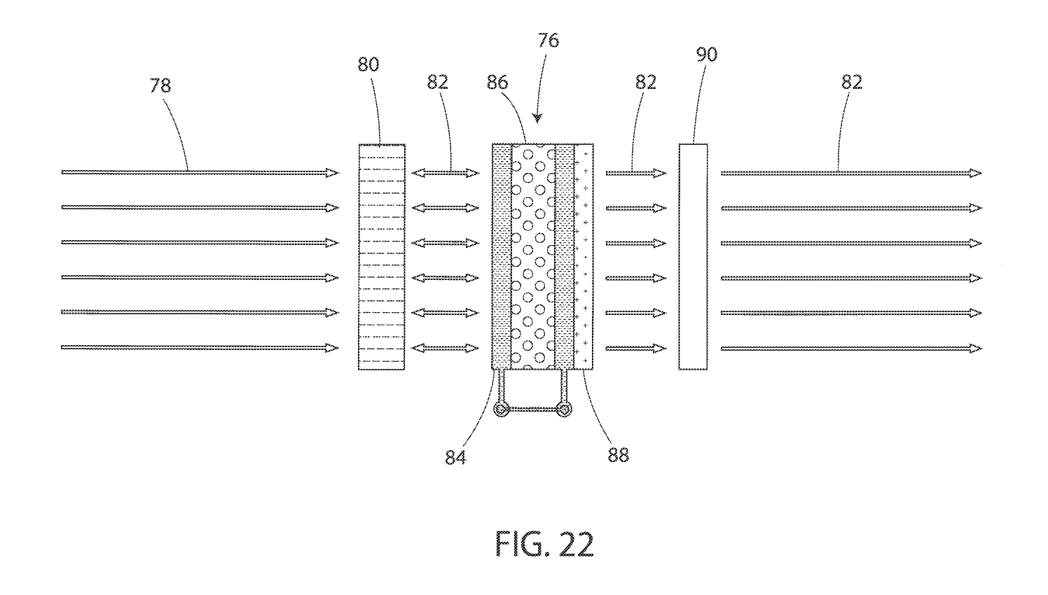

FIG. 22 is an exploded, cross-sectional diagram of a see-through OLED assembly on a sub-pixel level. As shown in FIG. 22, a light emitting portion 76 emits light both toward and away from the viewer, and natural or ambient light enters through the half-silvered layer 80, which also reflects the emitted light from the light emitting portion 76. Accordingly the light 82 between the half silvered layer 80 and the light emitting portion 76, as well as what is transmitted through to the viewer, is a mixture of natural or ambient light 78 and the emitted light.

The light emitting portion 76 is substantially the same as that in the OLED assembly, and includes an electrode 84 driving an active coloring emitter 86, and a single layer polarizer 88. The mixed light 82 passes through the single layer polarizer 88 and then through the viewing side substrate 88 toward the viewer.

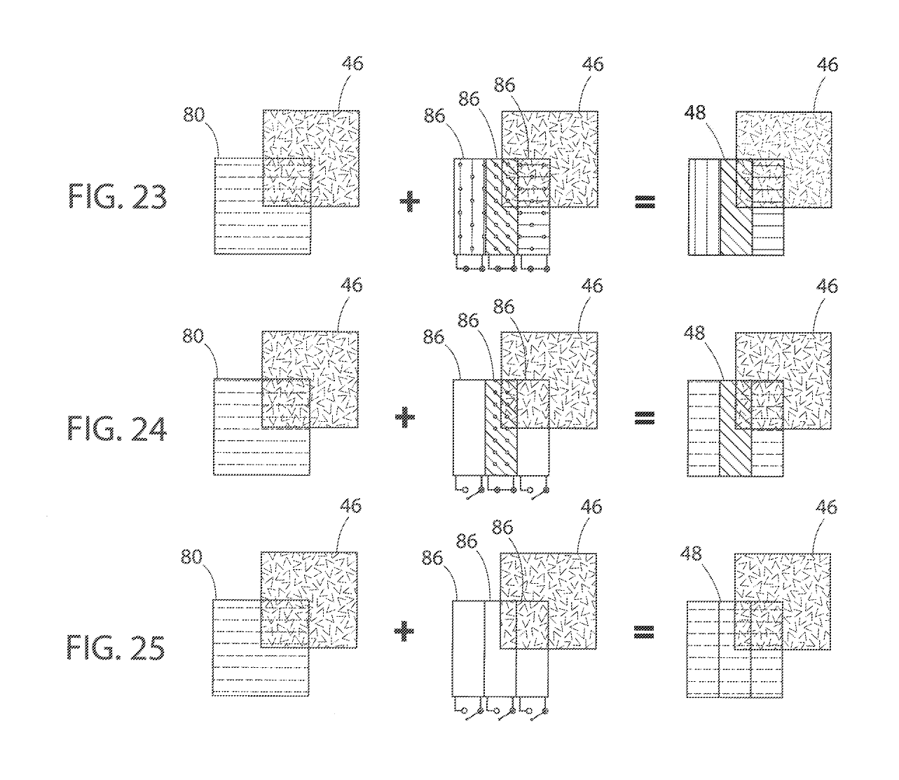

FIG. 23 is a diagram of a see-through OLED assembly producing a transparent white pixel. In this state, In this state, a group of three sub-pixel active color emitters 86 are driven by the electrode 84 to respectively emit red, green, and blue sub-pixel light, which mixes with the natural or ambient light and passes through the single layer polarizer 88 to create a transparent white pixel 48.

FIG. 24 is a diagram of a see-through OLED assembly producing a transparent color pixel. In this state, the red and blue sub-pixel active emitters 86 are not driven by the electrode 84, and therefore do not respectively produce red and blue light. The electrode 84, however, drives the green sub-pixel active emitter 86 to produce green light which mixes with the natural or ambient light passes through the single layer polarizer 88 to create a transparent green pixel 48.

FIG. 25 is a diagram of a see-through OLED assembly producing a “black,” half-silvered pixel. In this state, none of the active coloring emitters 86 are driven by the electrode 84, and therefore, do not produce light, but the natural or ambient light passes through the half-silvered layer and the single polarizing layer 88 which results in an transparent, half-silvered “black” pixel 48.

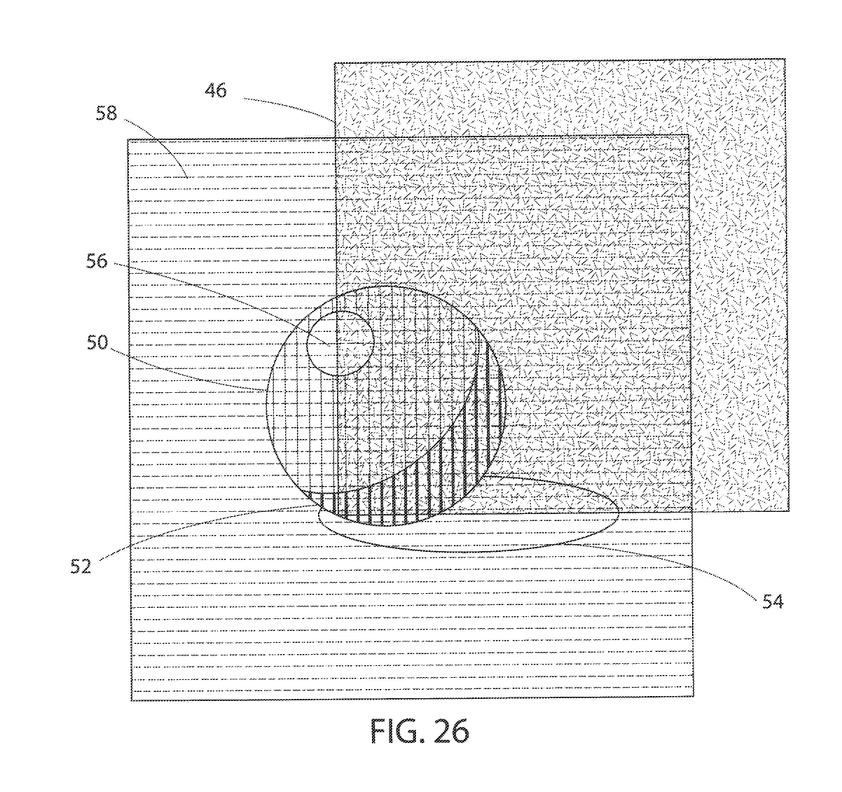

FIG. 26 is a diagram of a see-through OLED assembly displaying the exemplary image. None of the pixels are opaque. the non-image pixel area 58 is comprised of non-emitted, half-silvered pixels, the same as the shadow area 54. The white highlight area is transparent white, the half-silvered the lighter and darker red areas 50 and 52 are respectively lighter and darker transparent red.

The following table summarizes characteristics of LCDs, see through LCDs, OLEDs, and see-through OLEDs.

TABLE 1

| | | | | Non-image | | Non-Image |
|---|---|---|---|---|---|---|
| | | | | Pixel | Image Pixel | Pixel |
| Device | Image Pixel Opacity | | | Opacity | Luminance | Luminance |
| LCD | Always opaque | | | Always | Self-emitting: | Self-emitting: |
| | | | | opaque | total control | total control |
| See- | Only opaque when 100% black. Other | | | Always | Environmental: | No luminance |
| through | colors are some % transparent. Cannot | | | effectively | Less than total | (Luminance = |
| LCD | display white. | | | transparent | control | 0): Transparent |
| OLED | Always opaque | | | Always | Self-emitting: | None (black |
| | | | | opaque | total control | back plate) |
| See- | Color | Black | White | Transparent | Environmental + | No luminance |
| through | Some % | Fully | Some % | | Self- | (Luminance = |
| OLED | transparent | transparent | transparent | | emitting: | 0): Transparent |
| | | | | | Less than total | |
| | | | | | control | |

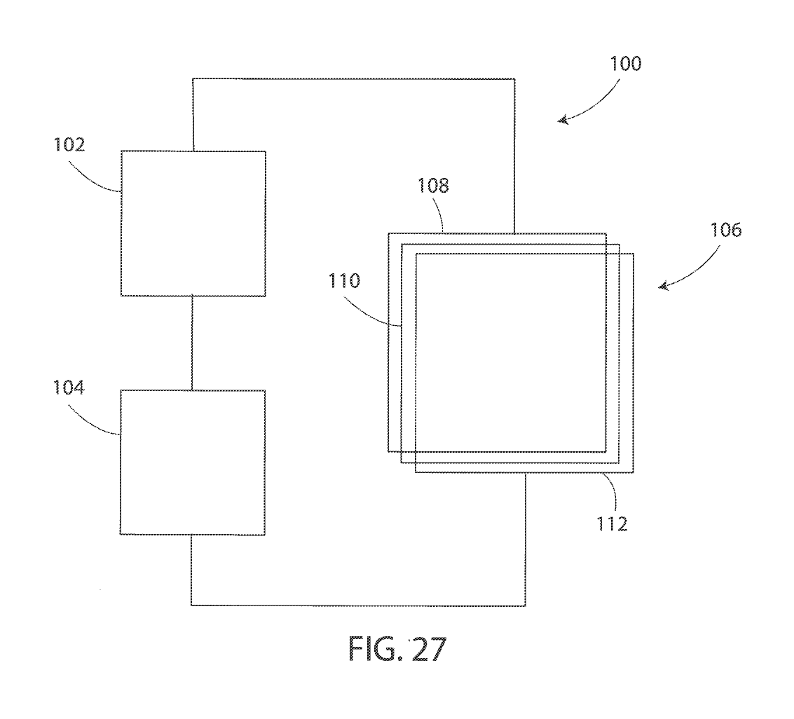

FIG. 27 is a block diagram of a system 100 in accordance with an embodiment of the present invention. As shown in FIG. 27, the system 100 includes a power source 102, an electronic controller 104, and a multi-layer device 106. Preferably, the electronic controller 104 takes the form of a microprocessor-based control system with appropriate software programming, as known to those skilled in the art.

Preferably, the power source 102 is a transparent photovoltaic layer to harvest solar energy to power the device, in combination with battery storage. According to other embodiments, a transparent photovoltaic layer alone, a non-transparent photovoltaic cell, one or more batteries, or an AC power source can be used without departing from the scope the present invention. Additionally, combinations of these power sources can be employed without departing from the scope the present invention.

The multi-layer device 106 has a viewing side and a second side opposite the viewing side. The multi-layer device 106 permits or prevents light to pass therethrough from the second side toward the viewing, and includes at least a coloring layer group 108 and a shutter layer group 110.

According to one embodiment, the coloring layer group 108 has a plurality of pixels, each pixel having at least three sub-pixels corresponding to different colors, and the shutter layer group 110 has a unique sub-pixel shutter corresponding to each sub-pixel of the coloring layer group 108. In this embodiment, the electronic controller 104, which is connected to the power source 102 and the multi-layer device 106, controls each sub-pixel shutter to selectively permit or prevent passage of an amount of light therethrough. The electronic controller 104 also controls control each combination of sub-pixel shutter and corresponding coloring layer sub-pixel to produce pixels on the viewing side that can be any of opaque black, at least substantially opaque white (subsequently described in greater detail), at least substantially opaque color (subsequently described in greater detail), transparent, transparent white, and transparent color.

According to another embodiment, the coloring layer group 108 has a plurality of pixels, each pixel having at least one sub-pixel corresponding to a color, and the shutter layer group 110 has a unique sub-pixel shutter corresponding to each sub-pixel of the coloring layer group 108. In this embodiment, the electronic controller 104 controls each sub-pixel shutter to selectively permit or prevent passage of an amount of light therethrough. The electronic controller 104 also controls each combination of sub-pixel shutter and corresponding coloring layer sub-pixel to produce pixels on the viewing side that can be any of opaque black, at least substantially opaque color, and transparent.

According to another embodiment, the multi-layer device also includes a diffusing layer group (subsequently described in greater detail) 112.

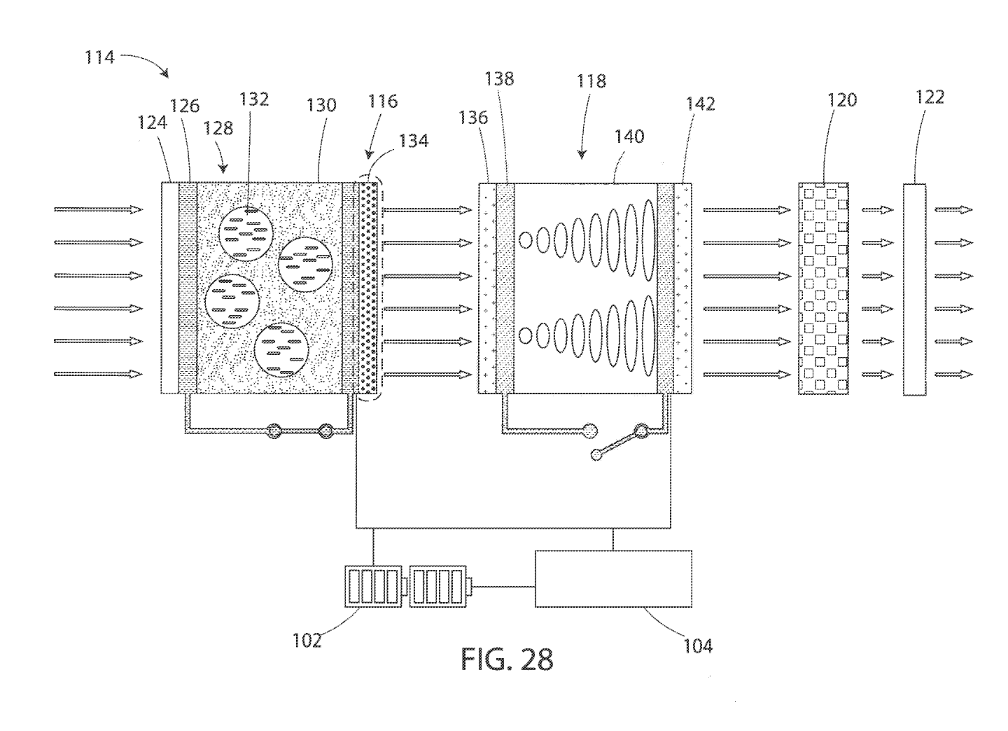

FIG. 28 is an exploded, cross-sectional diagram of a system 114 on a sub-pixel level in accordance with another embodiment of the present invention. In this embodiment, there is no backlight. The system 114 uses natural or ambient light. In addition to passing through sub-pixel shutters and passive color filters, light also passes through a pixelated diffusing layer group. The pixelated diffusing layer group controls whether the light passes through unaffected (pixel appears clear) or is scattered and appears substantially opaque white.

This embodiment has less control over luminance than a LCD, as it relies on light in its environment, like a see-through LCD. But this embodiment has substantial control over its opacity: opaque black, substantially opaque white, or substantially opaque color pixels can be present next to transparent pixels.

When used to block light through a window, the present embodiment uses the sun as its primary light source, instead of a backlight as in a LCD's optic system. But this embodiment can be used to block other light sources as well. For example, light from a projector, laser light, or an LED light bar, to name a few. In other words, this embodiment is not necessarily employed in conjunction with a window.

In more detail, as shown in FIG. 28, the system includes a diffusing layer group 116, a polarizing filter 118, a coloring layer group, and a viewing side substrate 122.

The diffusing layer group 116 helps to control the opacity and white value of the system 114. The diffusing layer group 116 achieves opacity values from completely transparent to diffuse white on a sub-pixel basis. In one embodiment, the diffusing layer group 116 achieves this using the electronic controller 104 and a polymer dispersed liquid crystal (PDLC).

“Privacy glass” is a phrase used in industry to describe windows that employ PDLCs and electronic controllers to make a window change from transparent to substantially opaque (usually white), and back again. Although in industry, the second state is referred to as “opaque,” but is actually substantially opaque, or what could be deemed translucent, not truly opaque. This is because in a powered state, an electric field in the PDLC orients the liquid crystal molecules to permit light to pass therethrough, but in an un-powered state, the crystals are not so oriented, and instead, scatter light so that the PDLC no longer appears clear. Some of the scattered light may pass through the PDLC in a viewing direction, and thus, the PDLC does not completely block light from passing therethrough. In other words, light passes through the PDLC, but the viewing side of the PDLC is not transparent. In this application, this is referred to as “substantially opaque”. Similarly, as used in this application, the phrase “at least substantially opaque” means a range from substantially opaque to completely opaque, in which light is blocked.

When a white PDLC is used in combination with the other layer groups, the pixelated diffuser layer functions to bring substantially white values to the resulting image. In color terms, this layer tints the image.

As shown in FIG. 28, the diffusing layer group 116 includes at least a rear or light receiving side substrate 124, and an electrode 126 controlled by the electronic controller 104 to drive a white polymer dispersed liquid crystal (PDLC) 128. The PDLC 128 includes a polymer 130 with liquid crystal molecules dispersed in the polymer 132. According to one embodiment, the diffusing layer group 116 also includes a prism layer 134 downstream of the white PDLC.

In another embodiment, rather than a PDLC, the diffusing layer group includes a suspended particle device (SPD) disposed on a substrate. An SPD is a thin film laminate of rod-like nano-scale particles is suspended in a liquid and placed between two pieces of glass or plastic, or attached to one layer. When no voltage is applied, the suspended particles are randomly organized, thus blocking and absorbing light. When voltage is applied, the suspended particles align and let light pass. Varying the voltage of the film varies the orientation of the suspended particles, thereby regulating the tint of the glazing and the amount of light transmitted. See, e.g., “Smart Glass” at https://en.wikipedia.org/wiki/Smart_glass (retrieved on Jul. 6, 2016) and references cited therein, all incorporated herein by reference.

According to one embodiment, the polarizing filter 118 includes a shutter layer group 118, including a first polarizing layer 136, an electrode 138 controlled by the electronic controller 104 to drive a liquid crystal layer 140, and a second polarizing layer 142 that is oriented to be orthogonal to the first polarizing layer 136. In operation, when the liquid crystal layer is un-powered (as shown in FIG. 28), the liquid crystals form a helix and turn the light ninety degrees. This turning aligns the light with the second polarizing layer 142, and the light is permitted to pass therethrough to a passive sub-pixel color filter 120 (coloring layer group 120), which colorizes the light. The colorized light then passes through the viewing side substrate 122. Preferably, the sub-pixel passive color filter would be red, green, or blue, and a group of three (red, green, and blue) would together blend to form a pixel.

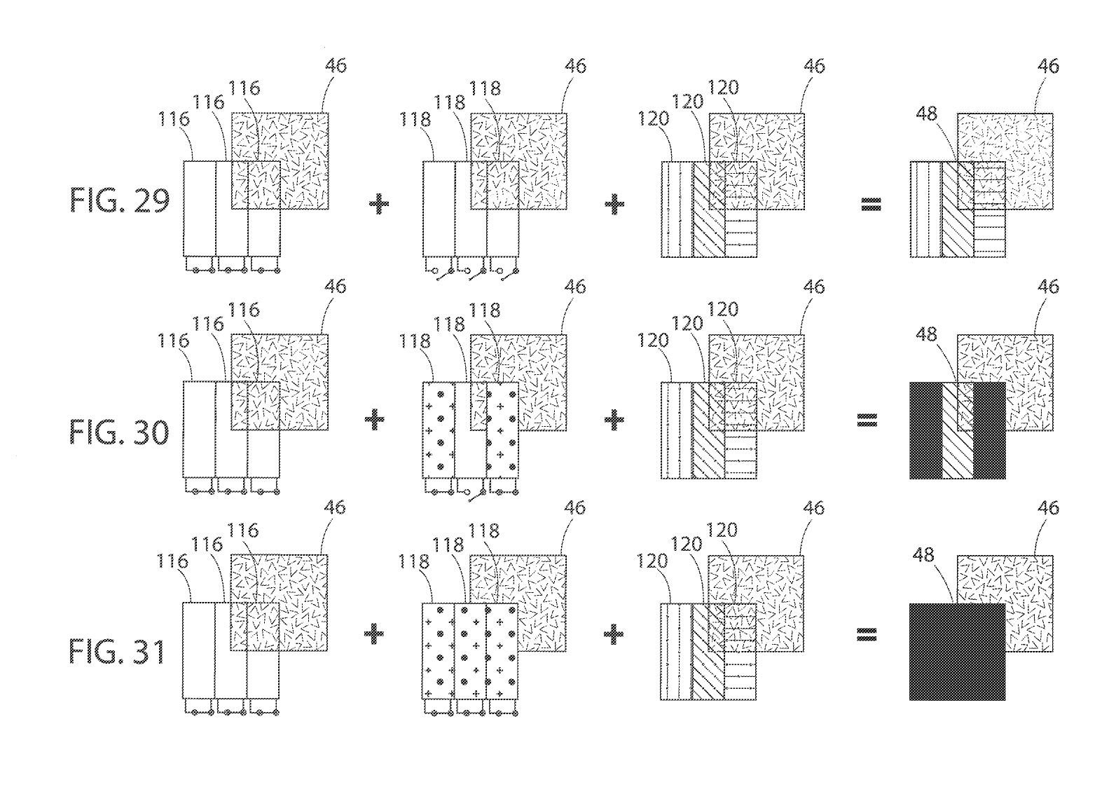

FIG. 29 is a diagram of the system 114 of FIG. 28 producing a transparent white pixel. In this state, each of the three sub-pixel PDLCs of the diffusing layer group 116 is powered, and therefore permits to pass therethrough. In the polarizing filter 118, each of the three sub-pixel shutters 118 is un-powered, thereby permitting light to pass therethrough, and the light passes respectively through the passive sub-pixel color filters 120 to produce a transparent white pixel 48.

FIG. 30 is a diagram of the system 114 of FIG. 28 producing a transparent color pixel. In this state, each of the three sub-pixel PDLCs of the diffusing layer group 116 is powered, and therefore permits to pass therethrough. In the polarizing filter 118, the red and blue sub-pixel shutters 118 are powered, thereby blocking light, but the green sub-pixel shutter 118 is un-powered, thereby permitting light to pass therethrough, and the light passes through the green passive sub-pixel color filter 120 to produce a transparent green pixel 48.

FIG. 31 is a diagram of the system 114 of FIG. 28 producing an opaque black pixel. In this state, each of the three sub-pixel PDLCs of the diffusing layer group 116 is powered, and therefore permits to pass therethrough. But each of the three sub-pixel shutters 118 are powered, thereby blocking light from passing therethrough. Therefore no light reaches the sub-pixel color filters 120, and an opaque black pixel 48 is produced.

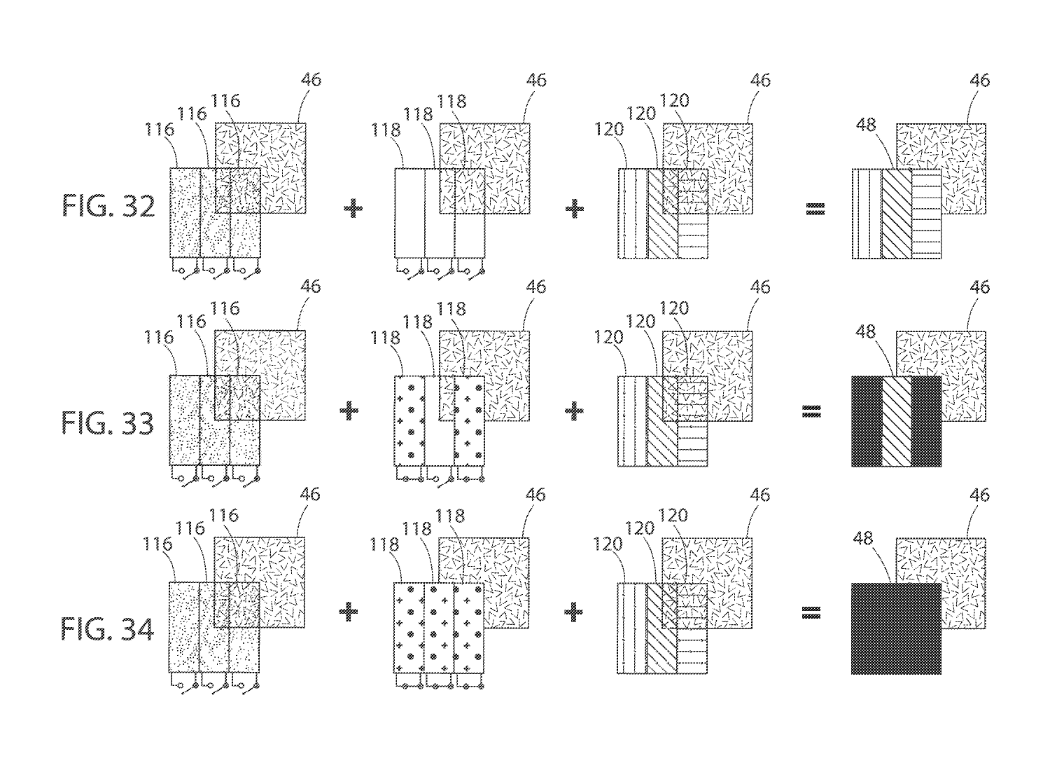

FIG. 32 is a diagram of the system 114 of FIG. 28 producing a substantially opaque white pixel. In this state, each of the three sub-pixel PDLCs of the diffusing layer group 116 is un-powered, and therefore scatters the received light. In the polarizing filter 118, each of the three sub-pixel shutters 118 is un-powered, thereby permitting what light reaches it to pass therethrough, and that light passes respectively through the three passive sub-pixel color filters 120 to produce a substantially opaque white pixel 48.

FIG. 33 is a diagram of the system 114 of FIG. 28 producing a substantially opaque color pixel. In this state, each of the three sub-pixel PDLCs of the diffusing layer group 116 is un-powered, and therefore scatters the received light. In the polarizing filter 118, the red and blue sub-pixel shutters 118 are powered, thereby blocking light, but the green sub-pixel shutter 118 is un-powered, thereby permitting light to pass therethrough, and the light passes through the green passive sub-pixel color filter 120 to produce a substantially opaque green pixel 48.

FIG. 34 is another diagram of the system 114 of FIG. 28 producing an opaque black pixel. In this state, each of the three sub-pixel PDLCs of the diffusing layer group 116 is un-powered, and therefore scatters the received light. But each of the three sub-pixel shutters 118 are powered, thereby blocking light from passing therethrough. Therefore no light reaches the sub-pixel color filters 120, and an opaque black pixel 48 is produced.

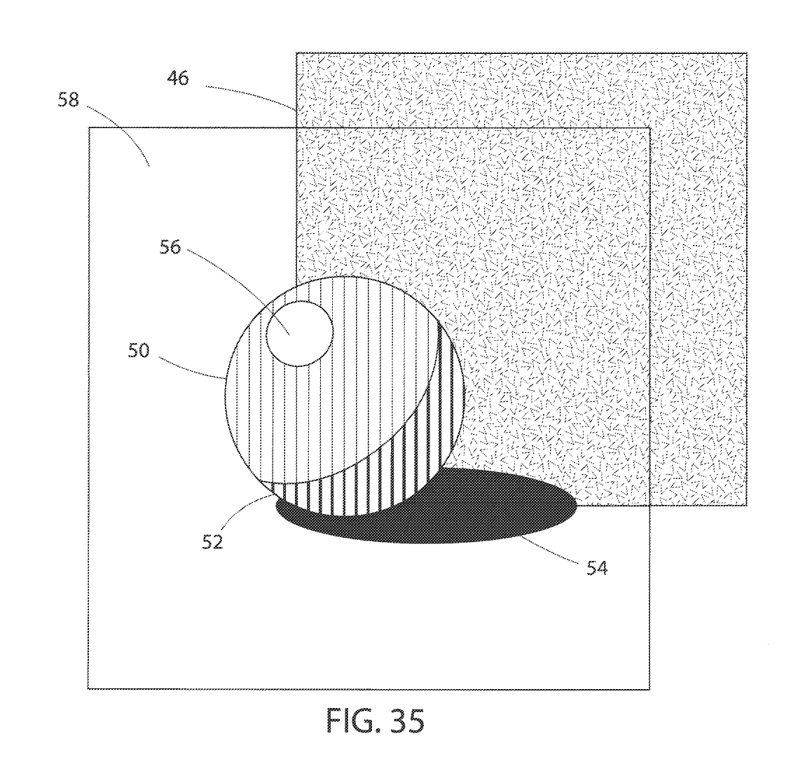

FIG. 35 is a diagram of the system 114 of FIG. 28 displaying the exemplary image. The non-image pixels 58 are transparent, the white highlight area 56 is substantially opaque white, the lighter and darker red areas 50 and 52 are respectively lighter and darker substantially opaque red, and the shadow area 54 is opaque black.

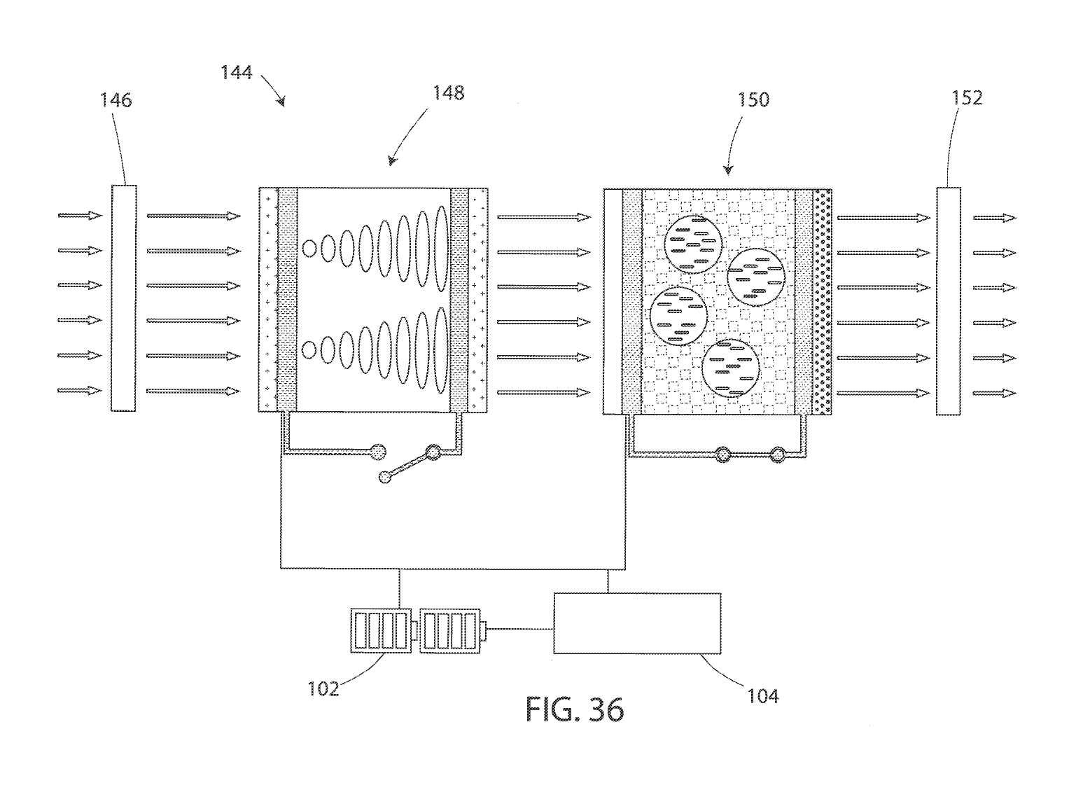

FIG. 36 illustrates a system 144 including a rear or light receiving side substrate 146, a polarizing filter or shutter layer group 148, a coloring layer group 150, and a viewing side substrate 152. The polarizing filter or shutter layer group 148 is substantially the same as the polarizing filter or shutter layer group 148 of system 114, and therefore, further description is omitted for brevity.

Although most PDLCs are white PDLCs, colored PDLCs can be employed, and can produce diffused, or substantially opaque colors. Preferably in this embodiment, the coloring layer group 150 is a coloring diffusing layer group 150, and includes a colored PDLC 150, which is substantially the same as the PDLC 128 of system 114 except that the PDLC 150 is colored, not white. Therefore, further description of the PDLC 150 is omitted for brevity.

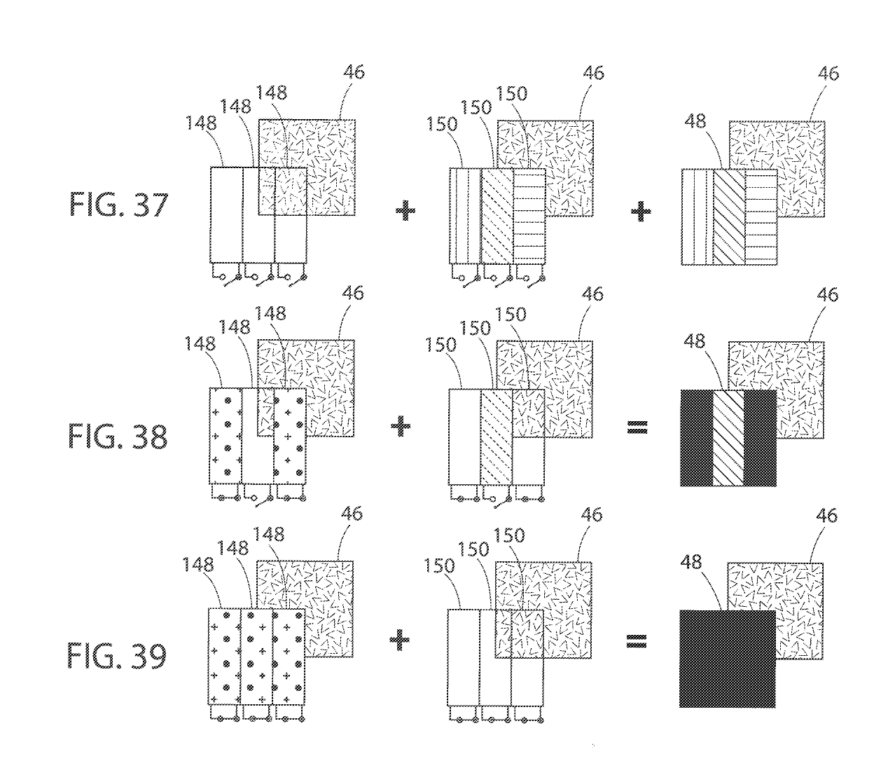

In FIG. 37, each of the sub-pixel shutters 148 are un-powered, thereby permitting light to pass therethrough, and each of the sub-pixel colored PDLCs (preferably red, green, and blue) 150 are un-powered, and therefore scatters the received light and colors the light that passes therethrough, producing a substantially opaque white pixel 48.

In FIG. 38, the red and blue sub-pixel shutters 148 are powered and therefore, block light, but the green sub-pixel shutter 148 is un-powered, and therefore permits light to pass therethrough. In the coloring layer group 150, the red and green PDLCs 150 are powered, thereby permitting light to pass therethrough, but the green PDLC 150 is un-powered, thereby scattering the received light and coloring the light that passes therethrough green, producing a substantially opaque green pixel 48.

In FIG. 39, all three of the sub-pixel shutters are powered and therefore, block light, so no light reaches the three powered PDLCs 150, producing an opaque black pixel 48.

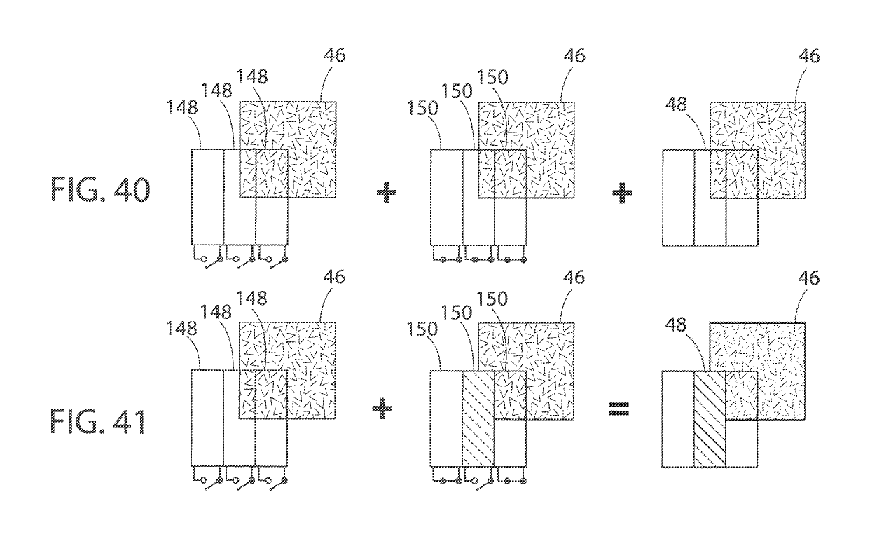

In FIG. 40, each of the sub-pixel shutters 148 are un-powered, thereby permitting light to pass therethrough, and each of the sub-pixel colored PDLCs 150 are powered, thereby permitting light to pass therethrough, and producing a transparent pixel 148.

In FIG. 41, each of the sub-pixel shutters 148 are un-powered, thereby permitting light to pass therethrough, and the red and blue sub-pixel shutters are powered, thereby permitting light to pass therethrough. But the green PDLC 150 is un-powered, thereby scattering the received light and coloring the light that passes therethrough green, producing a transparent green pixel 48.

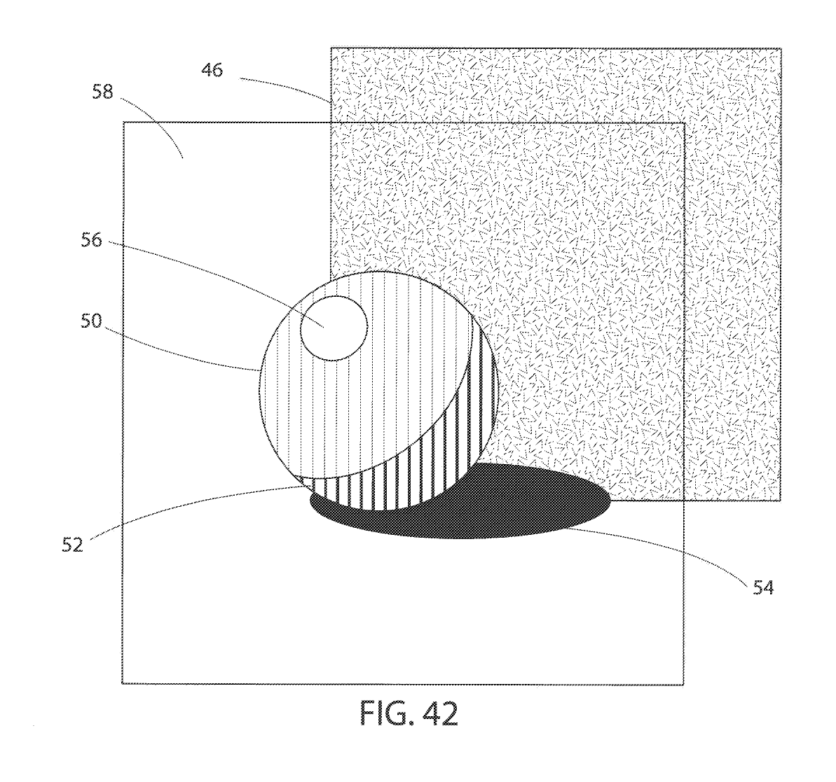

FIG. 42 is a diagram of the system 144 of FIG. 36 displaying the exemplary image. The non-image pixels 58 are transparent, the white highlight area 56 is substantially opaque white, the lighter and darker red areas 50 and 52 are respectively lighter and darker substantially opaque red, and the shadow area 54 is opaque black.

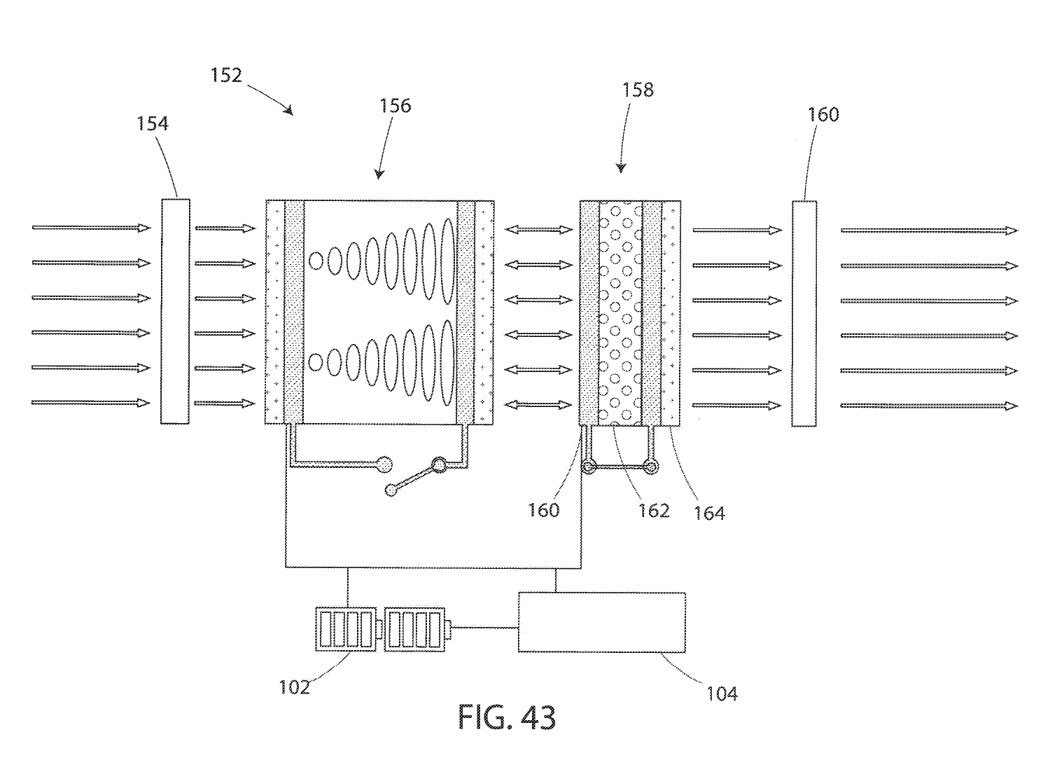

FIG. 43 is an exploded, cross-sectional diagram of a system 152 on a sub-pixel level in accordance with another embodiment of the present invention. The system 152 includes a rear or light receiving side substrate 154, a polarizing filter or shutter layer group 156, a coloring layer group 158, and a viewing side substrate 160. The polarizing filter or shutter layer group 156 is substantially the same as the polarizing filter or shutter layer group 148 of system 114, and therefore, further description is omitted for brevity.

The coloring layer group 158 preferably includes an electrode 160 controlled by the electronic controller 104. The electrode 160 drives an active coloring emitter 162, and the coloring layer group 158 also preferably includes a single layer polarizer 164 disposed on the viewing side of the active coloring emitter 162. Most preferably, the coloring layer group 158 includes an OLED.

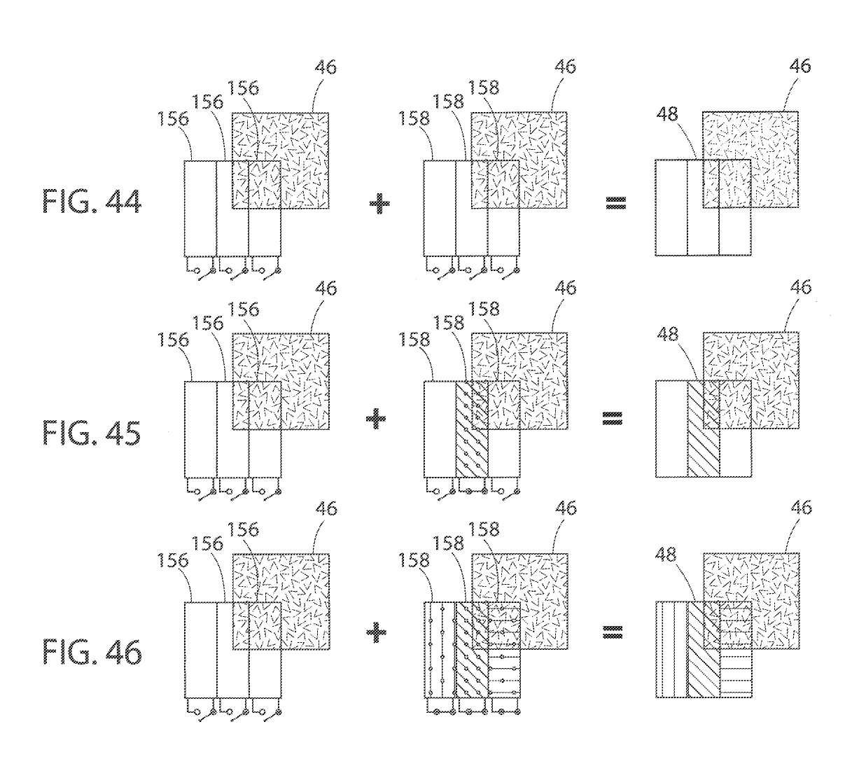

In the state depicted in FIG. 44, each of the sub-pixel shutters 156 of the shutter layer group 156 are un-powered, thereby permitting received light to pass therethrough, and each of the sub-pixel emitters 158 of the active coloring layer group 158 is un-powered, thereby not producing colored light. This configuration results in a transparent pixel 48.

In the state depicted in FIG. 45, each of the sub-pixel shutters 156 of the shutter layer group 156 are un-powered, thereby permitting received light to pass therethrough. The red and blue sub-pixel emitters 158 are un-powered, thereby not producing any light. The green sub-pixel emitter 158, however, is powered and emitting green light, thereby producing a transparent green pixel 48.

In the state depicted in FIG. 46, each of the sub-pixel shutters 156 of the shutter layer group 156 are un-powered, thereby permitting received light to pass therethrough, and each of the sub-pixel emitters 158 are powered, thereby respectively emitting red, green, and blue light and producing a transparent white pixel 48.

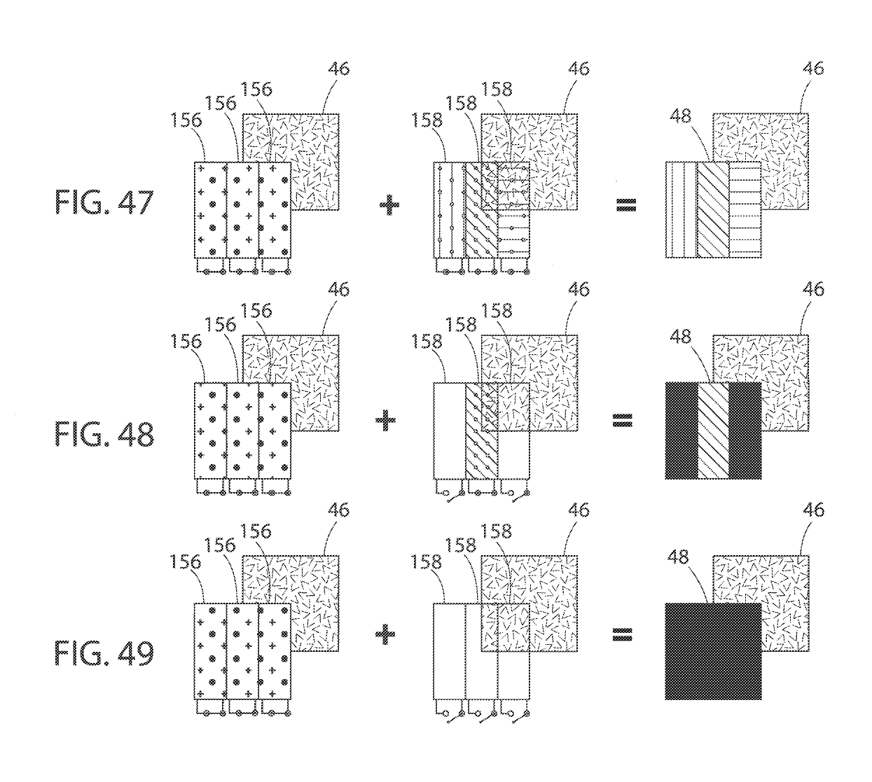

In the state depicted in FIG. 47, each of the sub-pixel shutters 156 of the shutter layer group 156 are powered, thereby blocking received light, and each of the sub-pixel emitters 158 are powered, thereby respectively emitting red, green, and blue light and producing an opaque white pixel 48.

In the state depicted in FIG. 48, each of the sub-pixel shutters 156 of the shutter layer group 156 are powered, thereby blocking received light, and the red and blue sub-pixel emitters 158 are un-powered, thereby not producing any light. But the green sub-pixel emitter 158 is powered and emitting green light, thereby producing an opaque green pixel 48.

In the state depicted in FIG. 49, each of the sub-pixel shutters 156 of the shutter layer group 156 are powered, thereby blocking received light, and each of the sub-pixel emitters 158 are un-powered, thereby not producing any light. This combination produces an opaque black pixel 48.

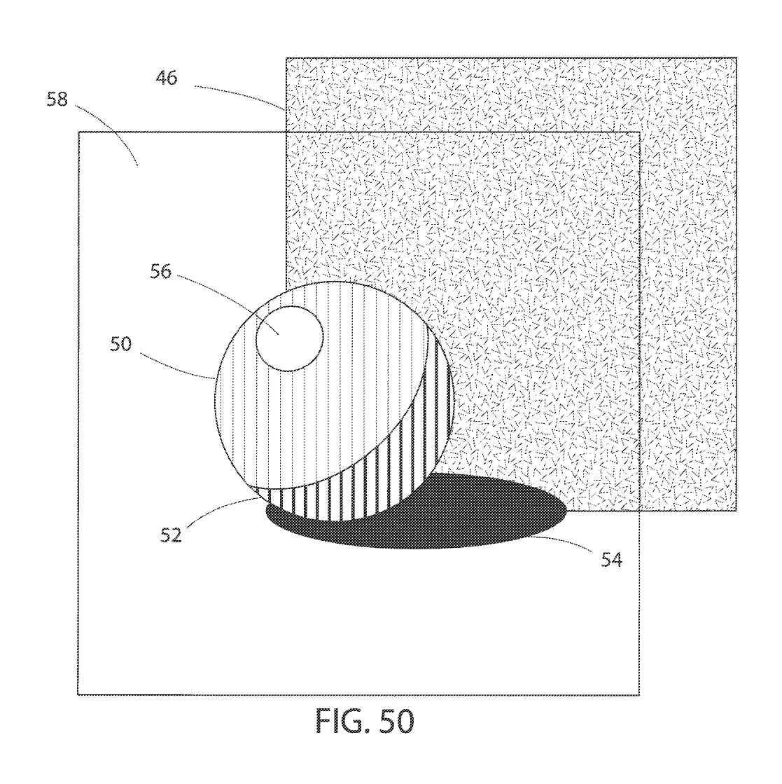

FIG. 50 is a diagram of the system 152 of FIG. 43 displaying the exemplary image. As preferably desired, the non-image pixels 58 are transparent, the white highlight area 56 is opaque white, the lighter and darker red areas 50 and 52 are respectively lighter and darker opaque red, and the shadow area 54 is opaque black.

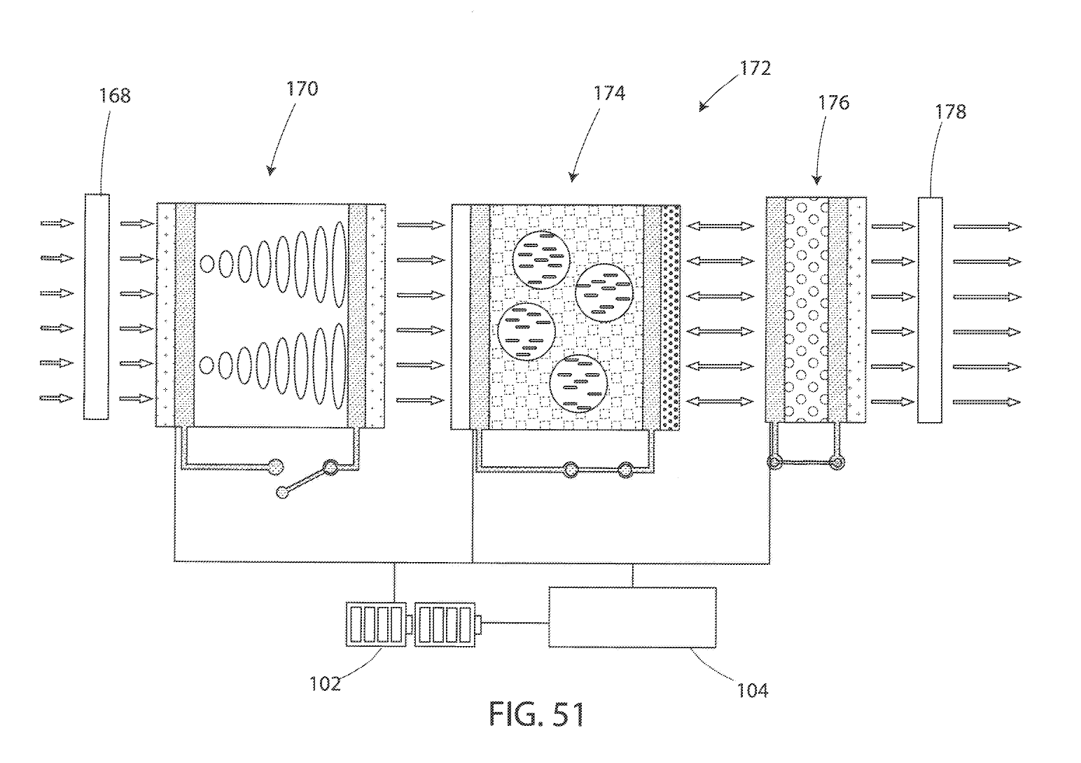

FIG. 51 is an exploded, cross-sectional diagram of a system 166 on a sub-pixel level in accordance with another embodiment of the present invention. The system 166 includes a rear or light receiving side substrate 168, a polarizing filter or shutter layer group 170, an active coloring layer group 172, and a viewing side substrate 178. The polarizing filter or shutter layer group 170 is substantially the same as the polarizing filter or shutter layer group 148 of system 114, and therefore, further description is omitted for brevity.

The coloring layer group 172 preferably includes both a coloring diffusion layer group 174 and an active color emitting layer group 176. The coloring diffusion layer group 174 is substantially similar to the previously-described coloring diffusing layer group 150, and further description is omitted for brevity. Similarly, the active color emitting layer group 176 is substantially similar to the previously-described coloring layer group 158, and further description is omitted for brevity.

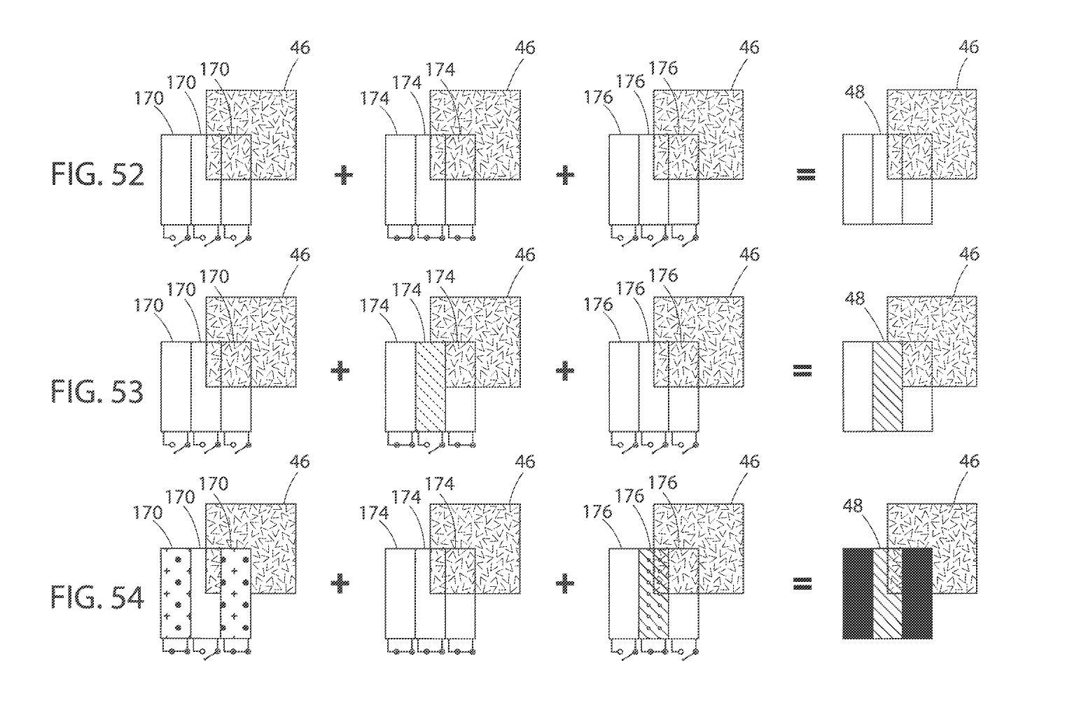

In FIG. 52, the configuration of un-powered sub-pixel shutters 170, powered PDLCs 174, and unpowered sub-pixel emitters 176 yields a transparent pixel 48. In FIG. 53, the configuration of un-powered sub-pixel shutters 170, an un-powered green PDLC, and unpowered sub-pixel emitters 176 yields a transparent green pixel 48. In FIG. 54, the configuration of an un-powered green sub-pixel shutters 170, powered blue and red sub-pixel shutters 170, powered PDLCs 174, and a powered green sub-pixel emitter with un-powered red and blue sub-pixel emitters 176 also yields a transparent green pixel 48.

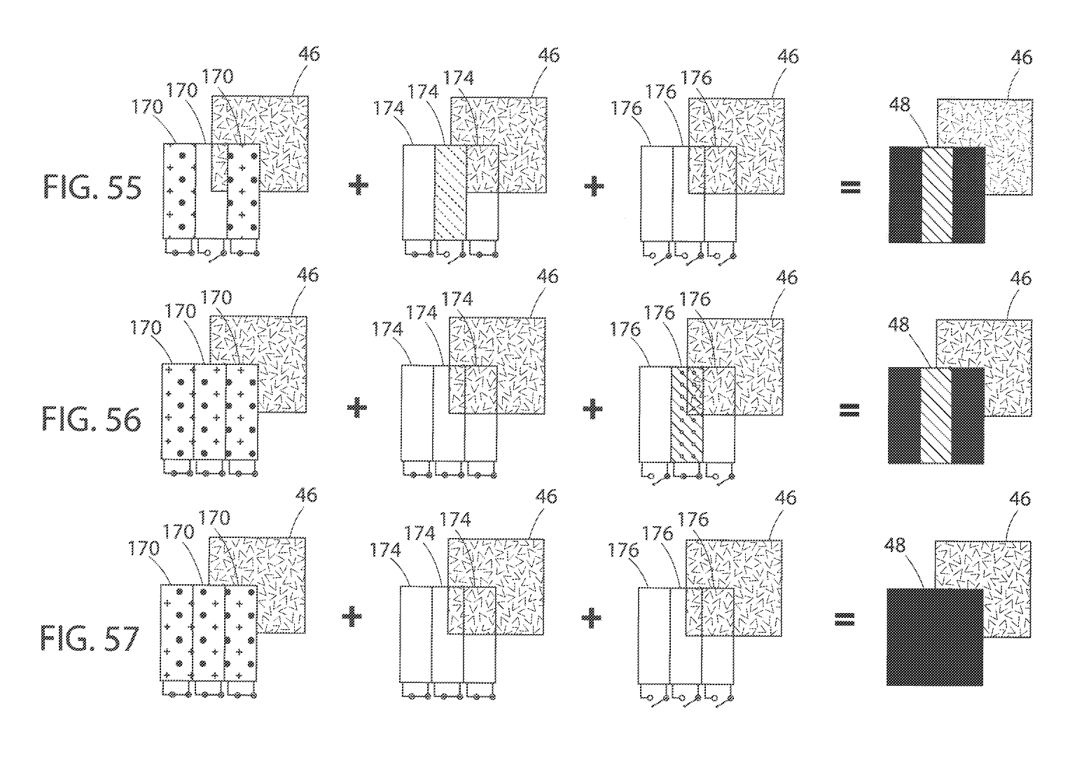

In FIG. 55, the combination of an un-powered green sub-pixel shutters 170, powered blue and red sub-pixel shutters 170, an un-powered green PDLC 174, and unpowered sub-pixel emitters 176 yields a substantially opaque green pixel 48. In FIG. 56, the combination of powered sub-pixel shutters 170, powered PDLCs 174, and a powered green sub-pixel emitter 176 yields an opaque green pixel 48. In FIG. 57, the combination of powered sub-pixel shutters 170, powered PDLCs 174, and unpowered sub-pixel emitters 176 yields an opaque black pixel 48.

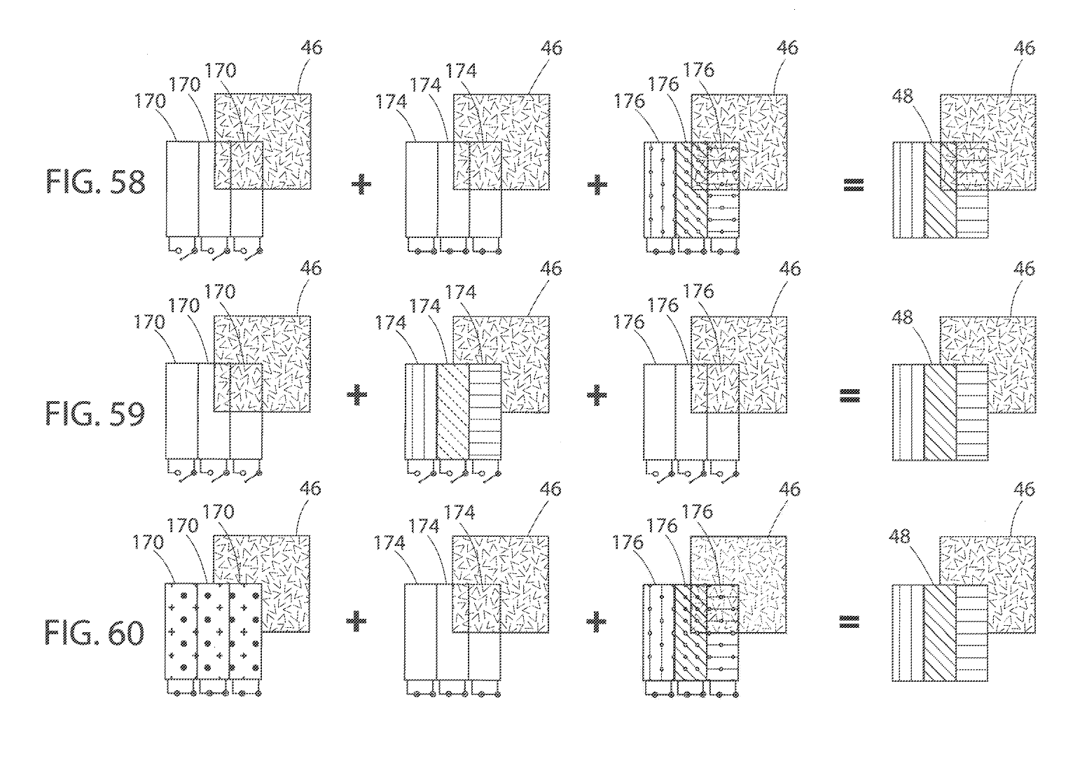

In FIG. 58, the combination of un-powered sub-pixel shutters 170, powered PDLCs 174, and powered sub-pixel emitters 176 yields a transparent white pixel 48. In FIG. 59, the combination of un-powered sub-pixel shutters 170, un-powered PDLCs 174, and un-powered sub-pixel emitters 176 yields a substantially opaque white pixel 48. In FIG. 60, the combination of powered sub-pixel shutters 170, powered PDLCs 174, and powered sub-pixel emitters 176 yields a opaque white pixel 48.

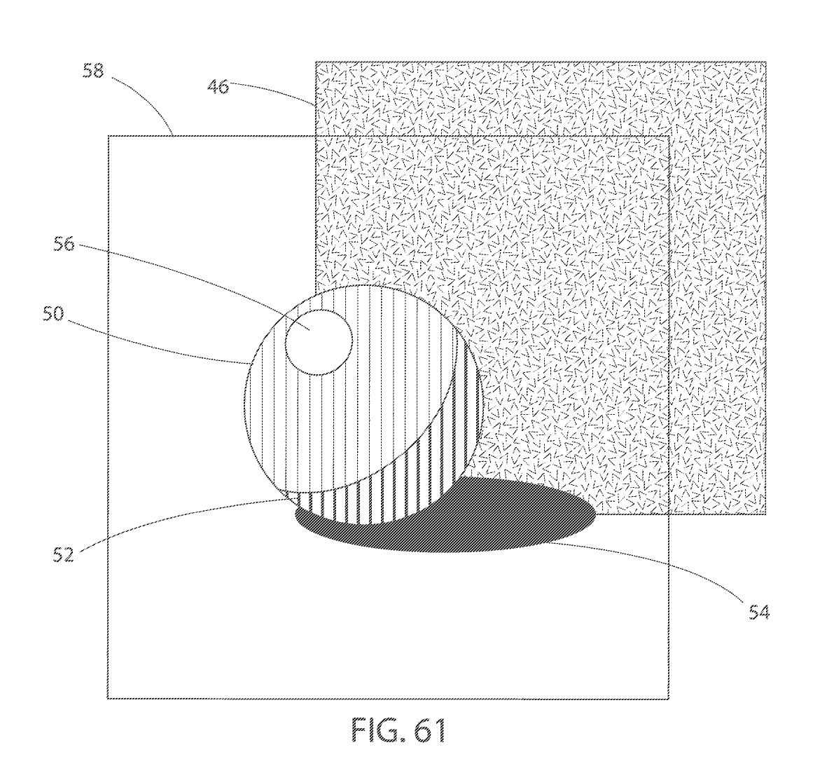

FIG. 61 is a diagram of the system of FIG. 51 displaying the exemplary image. As preferably desired, the non-image pixels 58 are transparent, the white highlight area 56 is opaque white, the lighter and darker red areas 50 and 52 are respectively lighter and darker opaque red, and the shadow area 54 is opaque black.

Other methods can be used in a shutter blocking layer group, such as electrochromic technology, SPDs, microblinds, and nano-crystals, as would e understood by one skilled in the art given the information described in this application.

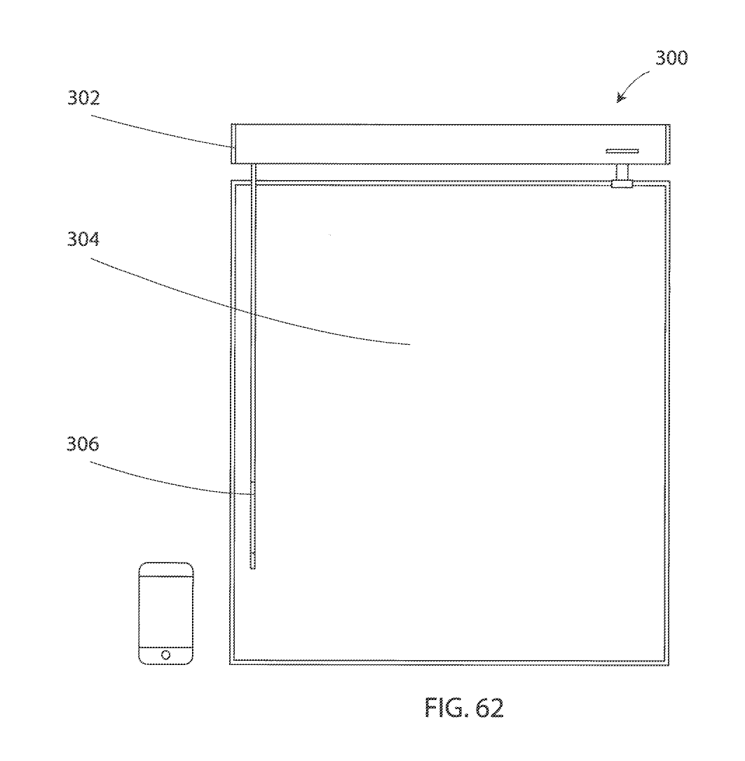

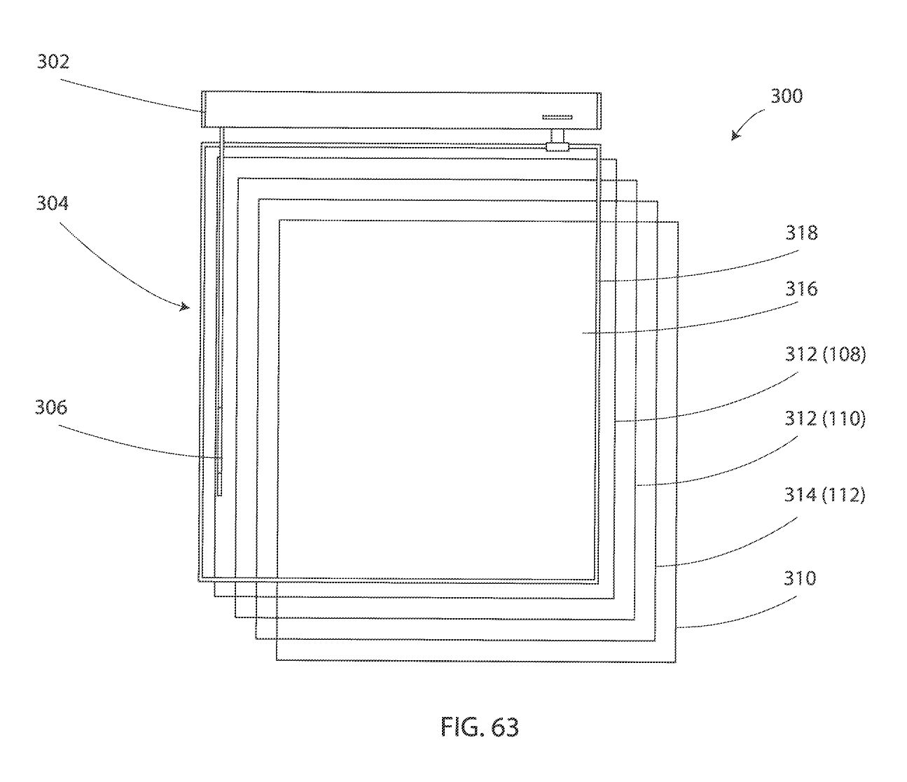

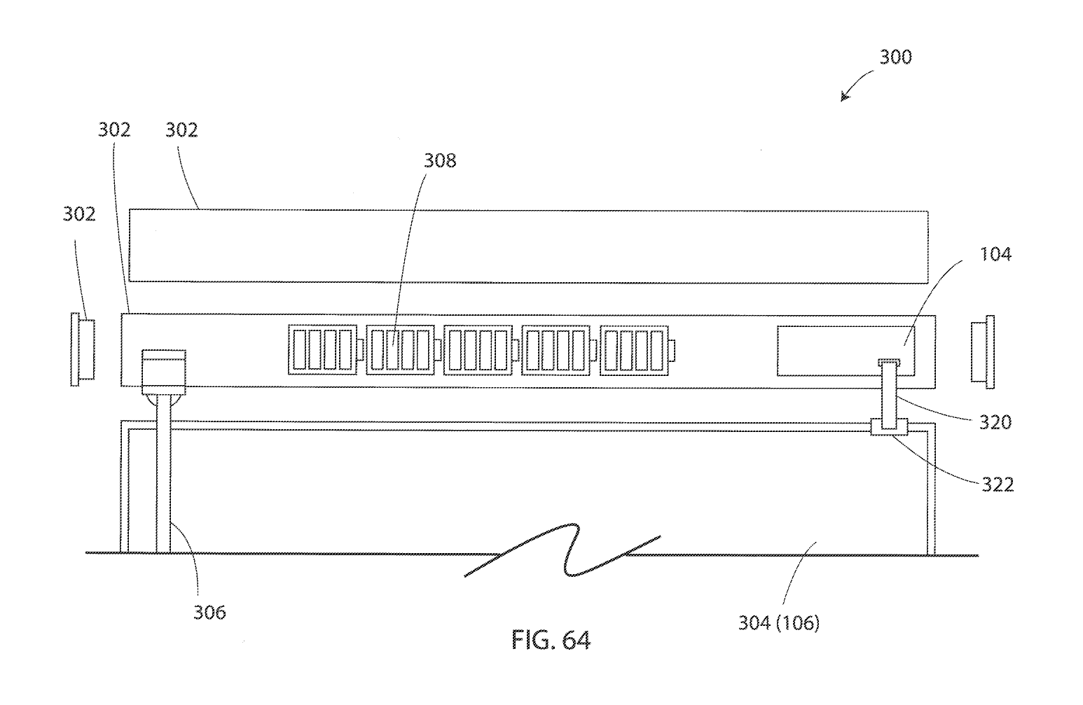

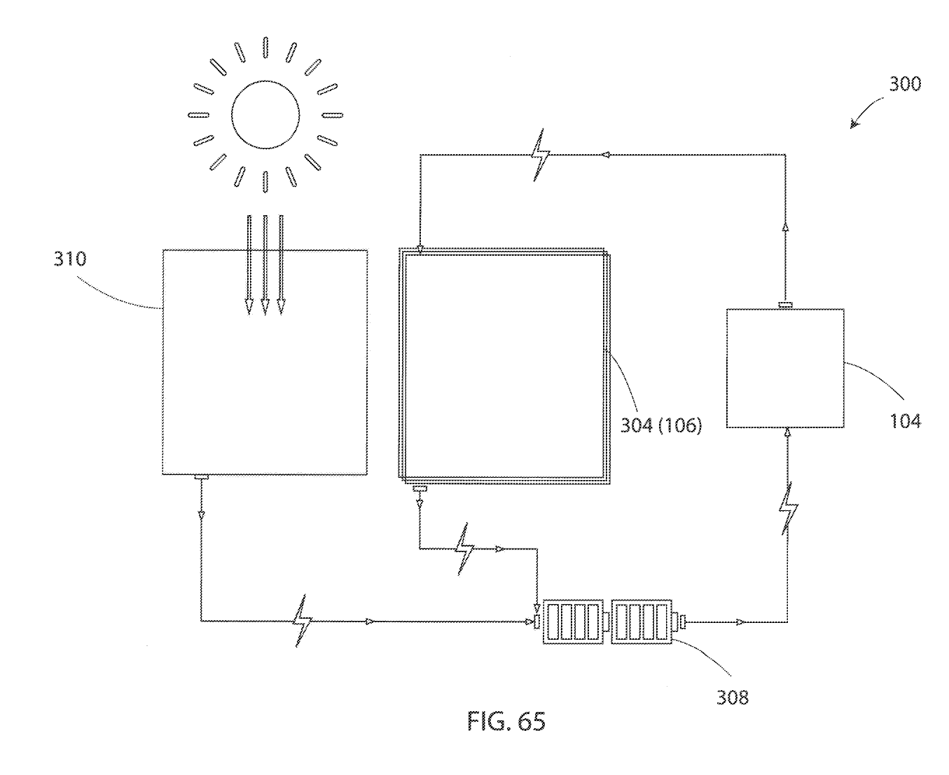

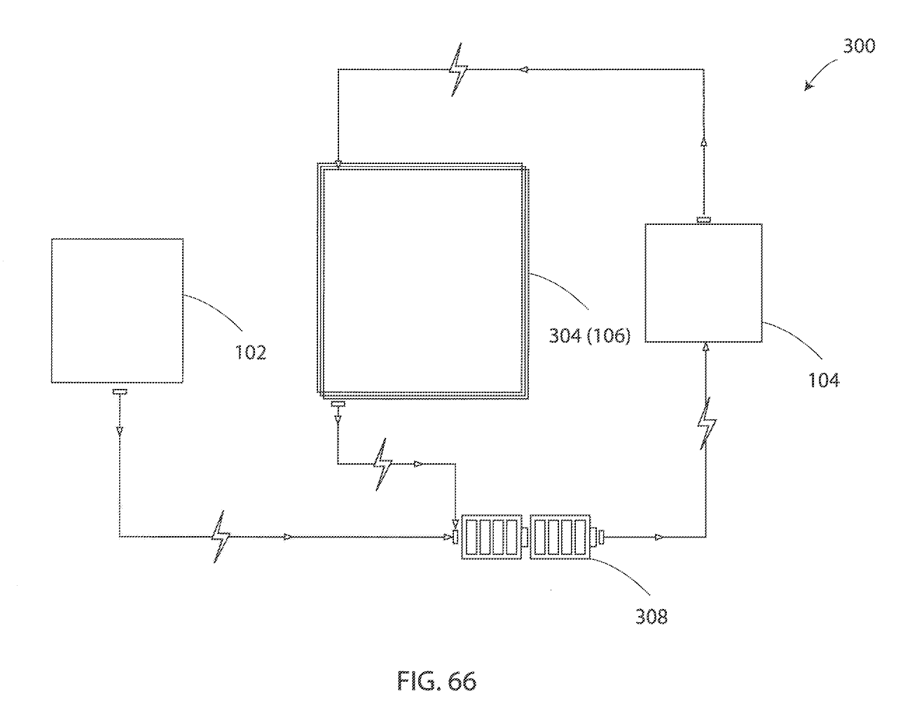

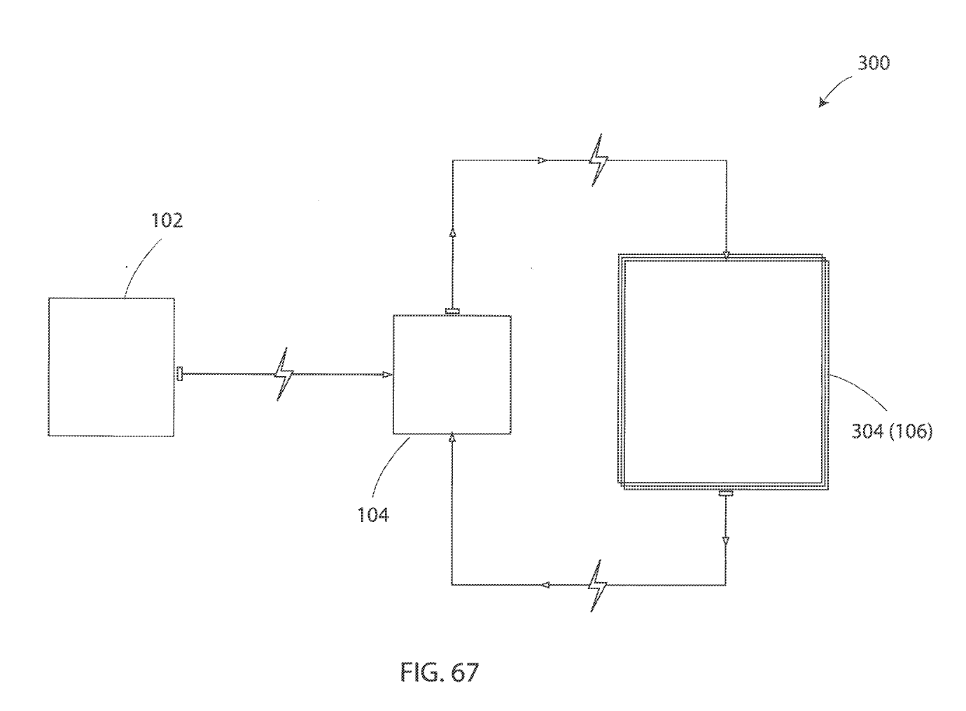

Other embodiments of the present invention are shown in FIGS. 62-67. According to one embodiment, as shown in FIG. 62, the inventive window covering system 300 includes three primary components that work together: a smart housing 302; a multi-layered, self-adhesive window multi-layered device 304; and an intuitive control wand 306.

According to one embodiment, the housing 302 is made of extruded aluminum, but one skilled in the will understand that other materials can be used without departing from the present invention's scope. The housing 302 includes the brain of the system that connects the multi-layered devices to a user. According to one embodiment, the housing 302 includes a memory, a processor, and input and output controllers. Preferably, the system 300 uses Wi-Fi to connect to other devices, such as smart phones tablets and other computing devices. One skilled in the art will appreciate, however, that other communication means can be employed without departing from the present invention's scope. For example, wired connections, Bluetooth, or other wireless communication means can be employed. Because the system can communicate with multiple devices, this communication provides greater control over the multi-layered device's appearance and settings, even remotely.

In one embodiment, the housing 302 includes an array of rechargeable batteries 308 that store the solar energy harnessed by the multi-layered device 304 to power the system 300 at night. In one embodiment, the system can be connected to a buildings power grid, and the batteries 308 could also be used to assist in everyday power consumption. According to one embodiment, the housing 302 has a minimal design aesthetic that allows it to blend seamlessly into any style environment.

Preferably, the multi-layered device 304 includes several thin film layers. A transparent photovoltaic layer 310 is positioned against the window and captures the sun's energy to charge the batteries 308. Two interior layers of the multi-layered device 304 utilize two different liquid crystal technologies: a transparent LCD 312 and a pixelated LC Diffuser 314. Together these two layers 312 and 314 enable the system 300 to go from being perfectly transparent to blackout, through grayscale and full color, thereby allowing for endless control over the appearance of the window. Additionally, it is preferable for one of the multi-layered device's layers, for example, the transparent photovoltaic layer 310 to include an adhesive for attaching the multi-layered device 304 to a window.

The fourth layer 316, which faces the interior of a room, is a protective layer that has a cut safe zone 318, which allows a user or installer (hereinafter referred to as a user for brevity) to cut the multi-layered device 304 and custom fit the multi-layered device 304 to a given window. According to one embodiment, the cut safe zone 318 is located only on the perimeter of the multi-layered device 304. In yet another embodiment, only a portion the perimeter of the multi-layered device 104 includes the cut safe zone 318. According to another embodiment, one or more cut safe zones can also be located within a central portion of the multi-layered device 304.

The system 300 is designed to be easy to install. A reversible mount can be attached to either a wall or a ceiling, or to window casing, by any fastening technology, such as screws, nails, or adhesive. Preferably, the housing 302 is self-locking with respect to the mount and, subsequent to securing the mount, only requires a user to press the housing 302 into the mount to secure the housing 302.

The cut safe zone 318 allows the self-adhesive multi-layered device 304 to be installed onto the glass pane, edge to edge, without any light leaks. Once the multi-layered device 304 and the housing 302 are installed, a ribbon cable 320 is plugged directly into a port 322 on the multi-layered device 304 to connect the multi-layered device 304 with the housing 302. For windows that open, where for example, there is a top stationary window and a lower window that opens, according to one embodiment, the ribbon cable 320 can auto retract and spool within the body of the housing 302 to ensure that the connection is not broken. Additionally, multiple systems 300 can be grouped by linking the respective housings together, allowing them to be controlled from a single control wand 306 or other device (such as the aforementioned smart phone, tablet, or computer). According to one embodiment, the respective housings are wired together, but one skilled in the art will appreciate that wireless technologies, such as Wi-Fi and Bluetooth, can also be employed to connect the housings without departing from the present invention's scope.

Designed to be familiar, the control wand 306 is connected to the housing 302 near an end of the housing 302, similar to the positioning of a rod (sometimes referred to as a wand) that controls the rotation of conventional horizontal blinds. Preferably, the control wand 306 includes a faceted grip.

The functioning of the control wand is also designed to be familiar. According to one embodiment, the control wand 306 is connected to the housing 302 such that twisting the control wand 306 controls the opacity of multi-layered device's image. The opacity can vary from completely blacked out to partially transparent, to transparent.

In addition, according to one embodiment, the control wand 306 is touch sensitive. Preferably, the control wand is capacitive. For example, the control wand is preferably connected to the housing 302 such that the user can slide his or her finger or fingers up and down on the capacitive wand 306 to change the vertical position of the image displayed on the multi-layered device 304. As a more specific example, one portion of the multi-layered device 304 can display an opaque image while another portion of the multi-layered device 304 displays a transparent or semi-transparent image. If the user slides his or her fingers up the control wand 306, the portion of the multi-layered device 304 displaying the opaque image decreases, and if the user slides their fingers down the control wand 106, the portion of the multi-layered device 304 displaying the opaque image increases.

For even more control, the system 300 effortlessly connects to a Wi-Fi or other remote control device to offer customized settings. Such customized settings can include, but are not limited to automated wakeups, variable moods, and vacation modes. For example, the interface on a tablet computer, smart phone, computer, or the like can be employed to adjust pattern and color displayed on the multi-layered device 304 to create customized and inspired spaces that set the perfect mood by altering the color of the natural sunlight.

In addition, the system 300 can be set to know when the user is away and to activate an predetermined automated program to change the multi-layered device's display at different times. The system 300 can also be set to wake the user up in the morning and relax the user in the evening with sunrise and sunset routines. Further, when the system 300 is connected to the user's devices, the system 300 can alert the user to meetings and appointments, calls, emails, and other important reminders. Preferably the system can also be connected to a user's home, for example, via a security system, and can alert the user to door openings, whether the oven is on, and whether the dishwasher cycle is complete.

In the summer, the multi-layered devices 304 of the system 300 can appear more opaque to block light and heat from entering, and in the winter, the multi-layered devices 304 can appear more transparent to use the available light and heat to illuminate and warm the space naturally.

According to one embodiment, the system 300 can be connected to current weather data for its exact location, and can be set to constantly adjust the multi-layered devices to allow in as much or as little natural light and heat from the sun as desired to help maintain a desired temperature, thereby offsetting the use of the building's HVAC (Heating, Ventilation, Air Conditioning) system.

By harvesting and storing solar energy to power itself, the system reduces the power needs of the user's home, efficiently saving the user time and money. The system's cost effective design always works for the user. They system's minimal use of materials and components means that it is lightweight and has a low shipping cost. Because the system 300 is energy independent, it quickly pays for itself.

In a workspace, the system can turn a board mom into a presentation theater, use alerts to keep a person informed and efficient, and maximize lighting for optimal working conditions.

In a retail environment, the system can customize and quickly change out window displays, provide blackout security when a store is closed, and streamline and optimize advertising campaigns across multiple stores simultaneously.

In an event space, the system can transform the space by providing curated, custom imagery for any special gathering, transition and control light from day into the evening, and engage guests with potential to control settings through their personal devices, such as tablets and phones.

In a residential setting, the system can transform windows into custom canvases for expression and design, intuitively control light and heat in a space, and connect to personal and home smart devices for greater control and capability.

In restaurants and bars, the system can transition decor throughout the day's service—creating different moods for different menus, control natural light for the optimal dining experience, and extend the establishment's theme into an engaging active environment.

In a healthcare environment, the system can provide optimized sunlight conditions for patients, allow patients to customize their rooms and create a sense of warmth through personalized messages and images, and create custom soothing patterns and welcoming ambient environments throughout the hospital or facility.

In hospitality environments, such as hotels, the system can provide full blackout capabilities for jet lagged travelers to sleep effectively, give each room a unique identity or allow guests to customize to their choosing, and transition the hotel's decor seasonally throughout the year.

In an educational environment, the system can Provide optimal sunlight conditions for focusing and learning, engage students with immersive patterns to tie to lesson plans, and provide the capability to present information on windows to engage the classroom in a whole new way.

In an entertainment venue or environment, the system can project shows, movies tv and sports, provide backdrops for plays or live shows, and compliment any activity, from yoga to cooking classes.

Another technology that could be used to create a diffusing layer is Suspended Particle Device technology in combination with a sub-pixel active matrix. SPD utilizes a thin film laminate of rod-like nano-scale particles suspended in a liquid and attached to a substrate. When no voltage is applied the particles are randomly oriented and tend to block and absorb light. When a voltage is applied the particles align and allow light to pass through. Varying the voltage varies the orientation of the particles, which gives the user control over how much light is transmitted.

The nano scale particles would be calibrated to control how they affect the light so as to achieve a number of specific results. This could be achieved in two ways; 1 By varying the amount of particles being suspended would affect transparency of the base state (no power applied) 2. By calibrating the color of the particles themselves.

The diffuse particles would be calibrated so that they create what appears to be a substantially opaque white when zero power is applied and the particles are randomly oriented. Further, when power is applied and the particles do align, transparency of the layer results.

When used as a shutter layer the SPD would be calibrated to block and absorb the light creating a range from substantially opaque black to transparent when driven by an active matrix on a sub-pixel level.

When used as a coloring layer group the SPD would be calibrated to create a transparent color in its base state. When used in combination with an active matrix on a sub-pixel level, wherein each pixel comprises a red SPD transparent sub-pixel, a green SPD transparent sub-pixel, and a blue SPD transparent sub-pixel. In this case SPD could be used to create an active matrix color filter layer group.

Additionally a coloring diffusing layer group could utilize specially calibrated SPD. Where in each pixel comprises a red SPD diffusing sub-pixel, a green SPD diffusing sub-pixel, and a blue SPD diffusing sub-pixel.

Although only a few embodiments of the present invention have been shown and described, the present invention is not limited to the described embodiments. Instead, it will be appreciated by those skilled in the art that changes may be made to these embodiments without departing from the principles and spirit of the invention. It is particularly noted that those skilled in the art can readily combine the various technical aspects of the various elements of the various exemplary embodiments that have been described above in numerous other ways, all of which are considered to be within the scope of the invention, which is defined by the appended claims and their equivalents.

1.-31. (canceled)

32. A system, comprising:
a power source;
a multi-layer device connected to the power source and having two sides: a viewing side and a second side opposite the viewing side, the multi-layer device permitting or preventing light to pass therethrough from the second side toward the viewing side, the multi-layer device comprising:
a coloring layer group having a plurality of pixels, each pixel having at least one sub-pixel corresponding to white or to at least one color; and
a shutter layer group having a unique sub-pixel corresponding to each sub-pixel of the coloring layer group; and
an electronic controller connected to the power source and the multi-layer device, and configured to:
control each shutter layer group sub-pixel to selectively permit or prevent passage of an amount of light therethrough to produce a pixel that ranges from transparent to opaque black; and
control each combination of coloring layer group sub-pixel and corresponding shutter layer group sub-pixel to produce a pixel on the viewing side that can be each of the following: transparent, transparent color or colors, transparent white, at least substantially opaque color or colors, at least substantially opaque white, opaque color or colors, opaque white, and opaque black.

33. The system according to claim 32, wherein the coloring layer group comprises an active light coloring emitter; and
wherein the electronic controller controls each combination of coloring layer group sub-pixel and corresponding shutter layer group sub-pixel to produce pixels on the viewing side that can range from transparent to each of the following: transparent color or colors, transparent white, at least substantially opaque color or colors, at least substantially opaque white, opaque color or colors, opaque white, and opaque black.

34. The system according to claim 33, wherein the coloring layer group comprises a plurality of pixels, each pixel having at least more than one sub-pixel corresponding to a color.

35. The system according to claim 33, wherein the coloring layer group comprises a plurality of pixels, each pixel having at least three sub-pixels corresponding to different colors.

36. The system according to claim 35, wherein three of the sub-pixels are red, green and blue.

37. The system according to claim 33, wherein the active light coloring emitter comprises one of:
an organic light emitting diode; or
quantum dots on a substrate.

38. The system according to claim 33, wherein the shutter layer group comprises one of:
a liquid crystal layer;
E-ink disposed between substrates;
a suspended particle device (SPD) disposed on a substrate;
microblinds disposed on a substrate;
nanocrystals embedded in glass;
quantum dots disposed on a substrate; or
an electrochromic coating disposed on a substrate.

39. The system according to claim 32, wherein the multi-layer device further comprises:
a diffusing layer group having a unique sub-pixel corresponding to each sub-pixel of the coloring layer group; and
wherein the electronic controller is configured to:
control each diffusing layer group sub-pixel to produce a pixel that ranges from transparent to substantially opaque white; and
control each combination of coloring layer group sub-pixel and corresponding shutter layer group sub-pixel to produce pixels on the viewing side that can range from transparent to each of the following: transparent color or colors, transparent white, at least substantially opaque color or colors, at least substantially opaque white, opaque color or colors, opaque white, and opaque black.

40. The system according to claim 39, wherein the coloring layer group comprises a plurality of pixels, each pixel having at least more than one sub-pixel corresponding to a color.

41. The system according to claim 39, wherein the coloring layer group comprises a plurality of pixels, each pixel having at least three sub-pixels corresponding to different colors.

42. The system according to claim 39, wherein the coloring layer group comprises a passive color filter.

43. The system according to claim 39, wherein the diffusing layer group comprises one of:
a polymer dispersed liquid crystal (PDLC) layer; or
a suspended particle device (SPD).

44. The system according to claim 39, wherein the power source is AC power.

45. The system according to claim 39, wherein the power source is a transparent photovoltaic layer.

46. The system according to claim 39, wherein the power source is a non-transparent photovoltaic cell.

47. The system according to claim 39, wherein the power source is one or more batteries.

48. The system according to claim 39, wherein the power source charges rechargeable batteries.

49. A method of producing an image on a viewing side of a multi-layer device, the multi-layer device being connected to a power source and also having a viewing side and a second side opposite the viewing side, the multi-layer device permitting or preventing passage of light therethrough toward the viewing side, the multi-layer device comprising a coloring layer group having a plurality of pixels, each pixel having at least one sub-pixel corresponding to a white or at least one color; and a shutter layer group having a unique sub-pixel corresponding to each sub-pixel of the coloring layer group; the method comprising:
with an electronic controller:
controlling each shutter layer group sub-pixel to produce a pixel that ranges from transparent to opaque black; and
controlling each combination coloring layer group sub-pixel and corresponding shutter layer group sub-pixel to produce a pixel on the viewing side that can be each of the following: transparent, transparent color or colors, transparent white, at least substantially opaque color or colors, at least substantially opaque white, opaque color or colors, opaque white, and opaque black.

50. The method according to claim 49, wherein the coloring layer group comprises an active light coloring emitter; and
wherein the method further comprises:
with the electronic controller, controlling each combination of coloring layer group sub-pixel and corresponding shutter layer group sub-pixel to produce pixels on the viewing side that can range from transparent to each of the following: transparent color or colors, transparent white, at least substantially opaque color or colors, at least substantially opaque white, opaque color or colors, opaque white, and opaque black.

51. The method according to claim 49, wherein the multi-layer device further comprises a diffusing layer group having a unique sub-pixel corresponding to each sub-pixel of the coloring layer group; and
wherein the method further comprises:
with the electronic controller:
controlling each diffusing layer group sub-pixel to produce a pixel that ranges from transparent to substantially opaque white; and
controlling each combination of coloring layer group sub-pixel and corresponding shutter layer group sub-pixel to produce pixels on the viewing side that range from transparent to each of the following: transparent color or colors, transparent white, at least substantially opaque color or colors, at least substantially opaque white, opaque color or colors, opaque white, and opaque black.

52. The method according to claim 51, wherein the coloring layer group comprises a passive color filter.
